(19) United States
(12) Patent Application Publication
(10) Pub. No.: US 2026/0239763 A1
(43) Pub. Date: Aug. 13, 2026

(54) PHOTODETECTOR

(71) Applicant: SONY SEMICONDUCTOR SOLUTIONS CORPORATION, KANAGAWA (JP)

(72) Inventors: KOICHI TAKEUCHI, KANAGAWA (JP); KOJI WADA, KANAGAWA (JP); TAKASHI OINOUE, KANAGAWA (JP)

(21) Appl. No.: 19/151,617

(22) PCT Filed: Jan. 19, 2024
(86) PCT No.: PCT/JP2024/001433

§ 371 Date: Jul. 28, 2025

(30) Foreign Application Priority Data
Feb. 3, 2023 (JP) 2023-015642

(51) Int. Cl. H10F 39/00

(52) U.S. Cl. CPC H10F 39/8067; H10F 39/807

(57) ABSTRACT

A photodetector includes: a photoelectric conversion section; and an optical layer provided to cover the photoelectric conversion section, in which the optical layer includes: a plurality of pillars arranged side by side in a plane direction of a layer to guide at least light to be detected among incident light to the photoelectric conversion section; and a filler provided to fill a space between the plurality of pillars, and a side surface of the pillar has a curved surface bulging toward an outside of the pillar.

### FIELD

The present disclosure relates to a photodetector.

### BACKGROUND

For example, as disclosed in Patent Literature 1, there is known a technique of controlling the direction of incident light by arranging a plurality of fine structures having a dimension smaller than the wavelength of light side by side in a plane direction. Since the structure has, for example, a columnar shape extending in a direction orthogonal to the plane direction or a shape based on the columnar shape, the structure is also referred to as a “pillar” in the present disclosure.

### CITATION LIST

### Patent Literature

Patent Literature 1: JP 2020-537193 A

### SUMMARY

### Technical Problem

Since the pillar is a fine structure, there is a possibility that the pillar falls down.

One aspect of the present disclosure suppresses pillar collapse.

### Solution to Problem

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and a filler provided to fill a space between the plurality of pillars, and a side surface of the pillar has a curved surface bulging toward an outside of the pillar.

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; a reflection suppressing film provided on a lower surface of the pillar; and a filler provided to fill a space between the plurality of pillars and cover the reflection suppressing film, and the reflection suppressing film includes: an upper end portion located on the lower surface of the pillar and having an upper surface of the reflection suppressing film; a lower end portion having a lower surface of the reflection suppressing film; and an intermediate portion located between the upper end portion and the lower end portion and having a width smaller than a width of the upper end portion.

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and a film provided to cover at least a side surface of the pillar.

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and a reflection suppressing film provided over upper surfaces of the plurality of pillars, and the reflection suppressing film includes: a first portion each located on the upper surface of the pillar corresponding; and a second portion connecting the first portions located on the upper surfaces of the pillars adjacent.

### BRIEF DESCRIPTION OF DRAWINGS

FIG. 1 is a diagram illustrating an example of a schematic configuration of a photodetector 100.

FIG. 2 is a diagram illustrating an example of a circuit configuration of a pixel 2.

FIG. 3 is a diagram illustrating an example of a schematic configuration of a pixel array section 1.

FIG. 4 is a diagram illustrating an example of a schematic configuration of an optical layer 6.

FIG. 5 is a diagram illustrating an example of a schematic configuration of an optical layer 6.

FIG. 6 is a diagram illustrating an example of a schematic configuration of a pillar 62 and a peripheral structure thereof.

FIG. 7 is a diagram illustrating an example of a schematic configuration of a pillar 62 and a peripheral structure thereof.

FIG. 8 is a diagram illustrating an example of a pillar 62 and a peripheral structure thereof.

FIG. 9 is a diagram illustrating an example of a manufacturing method.

FIG. 10 is a diagram illustrating an example of a manufacturing method.

FIG. 11 is a diagram illustrating an example of a manufacturing method.

FIG. 12 is a diagram illustrating an example of a manufacturing method.

FIG. 13 is a diagram illustrating an example of a manufacturing method.

FIG. 14 is a diagram illustrating an example of a schematic configuration of an optical layer 6.

FIG. 15 is a diagram illustrating an example of a manufacturing method.

FIG. 16 is a diagram illustrating an example of a manufacturing method.

FIG. 17 is a diagram illustrating an example of a schematic configuration of an optical layer 6.

FIG. 18 is a diagram illustrating an example of a manufacturing method.

FIG. 19 is a diagram illustrating an example of an effective refractive index.

FIG. 20 is a diagram illustrating an example of an effective refractive index.

FIG. 21 is a diagram illustrating an example of a schematic configuration of an optical layer 6.

FIG. 22 is a diagram illustrating an example of a planar layout of a pillar 62.

FIG. 23 is a diagram illustrating an example of cross-sectional shapes of a pillar 62 and a film 67.

FIG. 24 is a diagram illustrating an example of cross-sectional shapes of a pillar 62 and a film 67.

FIG. 25 is a diagram illustrating an example of cross-sectional shapes of a pillar 62 and a film 67.

FIG. 26 is a diagram illustrating an example of a schematic configuration of an optical layer 6.

FIG. 27 is a diagram illustrating an example of a schematic configuration of an optical layer 6.

FIG. 28 is a diagram illustrating an example of a schematic configuration of an optical layer 6.

FIG. 29 is a diagram illustrating an example of a schematic configuration of an optical layer 6.

FIG. 30 is an enlarged view of a constriction C and its periphery.

FIG. 31 is a diagram illustrating an example of a schematic configuration of an optical layer 6.

FIG. 32 is a diagram illustrating an example of a schematic configuration of an optical layer 6.

FIG. 33 is a diagram illustrating an example of a manufacturing method.

FIG. 34 is a diagram illustrating an example of a manufacturing method.

FIG. 35 is a diagram illustrating an example of a manufacturing method.

FIG. 36 is a diagram illustrating an example of a manufacturing method.

FIG. 37 is a diagram illustrating an example of a manufacturing method.

FIG. 38 is a diagram illustrating an example of a manufacturing method.

FIG. 39 is a diagram illustrating an example of a manufacturing method.

FIG. 40 is a diagram illustrating an example of a manufacturing method.

FIG. 41 is a diagram illustrating an example of a manufacturing method.

FIG. 42 is a diagram illustrating an example of a manufacturing method.

FIG. 43 is a diagram illustrating an example of a manufacturing method.

FIG. 44 is a diagram illustrating an example of a manufacturing method.

FIG. 45 is a diagram illustrating an example of a manufacturing method.

FIG. 46 is a diagram illustrating an example of a manufacturing method.

FIG. 47 is a diagram illustrating an example of a manufacturing method.

FIG. 48 is a diagram illustrating an example of a manufacturing method.

### DESCRIPTION OF EMBODIMENTS

Hereinafter, embodiments of the present disclosure will be described in detail with reference to the drawings. Note that, in the following embodiments, the same elements are denoted by the same reference signs, and redundant description may be omitted. The same reference signs may be used for different meanings between different embodiments, and in this case, may be interpreted according to the description in the embodiment.

The present disclosure will be described according to the following order of items.
0. Example of Photodetector
1. First Embodiment
2. Second Embodiment
3. Third Embodiment
4. Fourth Embodiment
5. Conclusion

### 0. Example of Photodetector

One of the disclosed techniques is a photodetector. Hereinafter, a case where the photodetector is an imaging apparatus will be described as an example. Note that imaging and images in the imaging apparatus may be understood as meanings including imaging and video within a range without contradiction, and these terms may be appropriately read.

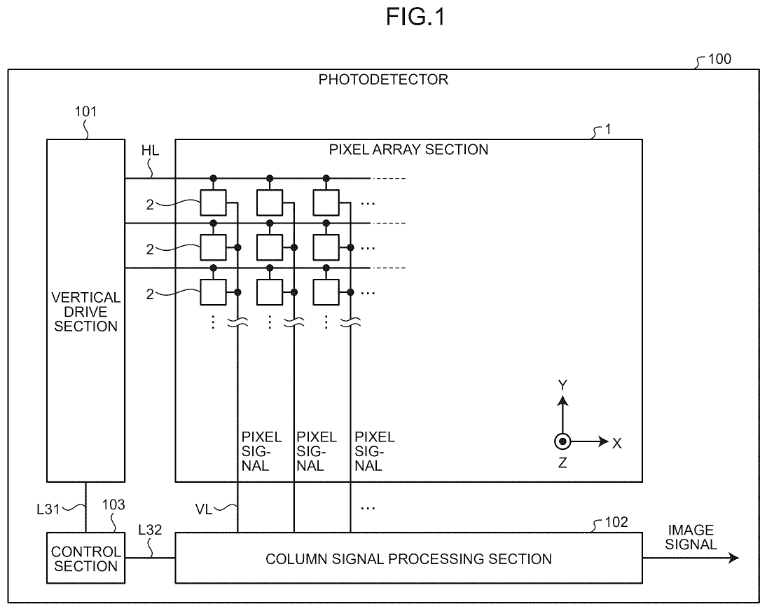

FIG. 1 is a diagram illustrating an example of a schematic configuration of a photodetector 100. The photodetector 100 includes a pixel array section 1, a vertical drive section 101, a column signal processing section 102, and a control section 103. For convenience, an XYZ system for the pixel array section 1 is also illustrated. The X-axis direction and the Y-axis direction (XY planar direction) correspond to the array direction. The X-axis direction is also referred to as a horizontal direction, a row (line) direction, or the like. The Y-axis direction is also referred to as a vertical direction, a column direction, or the like.

The pixel array section 1 includes a plurality of pixels 2. The plurality of pixels 2 are arranged in a two-dimensional manner (for example, a two-dimensional lattice shape) in the row direction and the column direction. The pixel 2 includes a photoelectric conversion section, and generates and outputs a voltage signal corresponding to the amount of incident light. The output voltage signal is referred to as a pixel signal. The pixel 2 also includes a circuit (pixel circuit) for light reception by the photoelectric conversion section, conversion into a voltage signal, and the like. The pixel signal from the pixel 2 is transmitted to the column signal processing section 102 via the signal line VL.

The vertical drive section 101 is connected to the pixel array section 1 via a signal line HL. For each row of the pixel array section 1, one or more signal lines HL extend from the vertical drive section 101 in the pixel array section 1, and are commonly connected to the pixels 2 located in the same row. The vertical drive section 101 supplies a control signal to the corresponding pixel 2 via the signal line HL.

The column signal processing section 102 is connected to the pixel array section 1 via a signal line VL. For each column of the pixel array section 1, one signal line VL extends from the column signal processing section 102 in the pixel array section 1 and is commonly connected to the pixels 2 located in the same column. The column signal processing section 102 processes the image signal from each pixel 2 for each column of the pixel array section 1. An example of the processing is analog to digital (AD) conversion processing and the like. The processed image signal is output as an image signal.

The control section 103 controls the entire photodetector 100. For example, the control section 103 generates a control signal for controlling the vertical drive section 101 and supplies the control signal to the vertical drive section 101. A signal line for this purpose is referred to as a signal line L31 in the drawing. Furthermore, the control section 103 generates a control signal for controlling the column signal processing section 102 and supplies the control signal to the column signal processing section 102. A signal line for this purpose is referred to as a signal line L32 in the drawing.

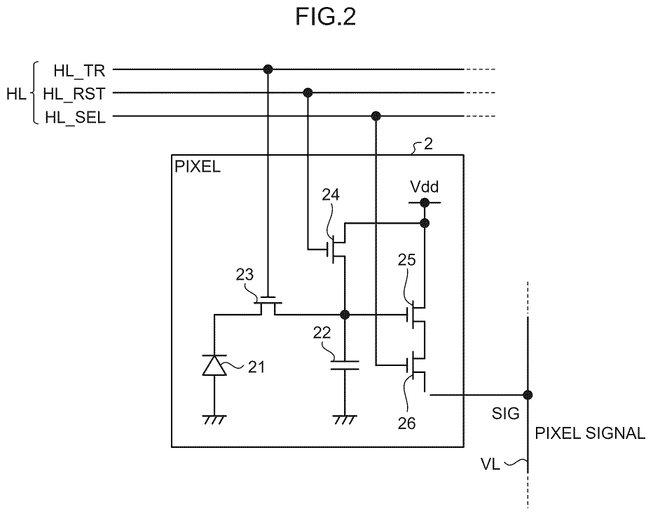

FIG. 2 is a diagram illustrating an example of a circuit configuration of the pixel 2. In this example, three signal lines HL are connected to the pixel 2. The signal lines HL are referred to as a signal line HL TR, a signal line HL RST, and a signal line HL SEL in the drawing so that the signal lines HL can be distinguished from one another. A power supply line Vdd is also illustrated.

The pixel 2 includes a photoelectric conversion section 21 and a pixel circuit. As components of the pixel circuit, a charge holding section 22 and transistors 23 to 26 are exemplified. Here, it is assumed that each of the transistors 23 to 26 is a field effect transistor (FET). The FET may be a MOSFET.

In the following description, the drain and the source of the transistor are also referred to as current terminals. The gate is also referred to as a control terminal. Connecting a transistor between two elements means that one current terminal (one of a drain and a source) is connected to one element and the other current terminal (the other of the drain and the source) is connected to the other element.

The photoelectric conversion section 21 generates and accumulates charges according to the amount of received light. The illustrated photoelectric conversion section 21 is a photodiode whose anode is grounded.

The charge holding section 22 holds the charge accumulated in the photoelectric conversion section 21. Examples of the charge holding section 22 include a floating diffusion capacitance, a capacitor, and the like.

The transistor 23 is a transfer transistor that is connected between the photoelectric conversion section 21 and the charge holding section 22 and transfers the charge accumulated in the photoelectric conversion section 21 to the charge holding section 22. A control terminal of the transistor 23 is connected to the signal line HL TR. On and off (the conductive state and the non-conductive state) of the transistor 23 are controlled by the control signal from the signal line HL TR.

The transistor 24 is a reset transistor that is connected between the charge holding section 22 and the power supply line Vdd and discharges the charge of the charge holding section 22 to the power supply line Vdd. A control terminal of the transistor 24 is connected to the signal line HL RST. On and off of the transistor 24 are controlled by a control signal from the signal line HL RST. Note that by turning on the transistor 23, the transistor 24 is also connected to the photoelectric conversion section 21, so that the charge accumulated in the photoelectric conversion section 21 can also be discharged to the power supply line Vdd.

The transistor 25 is connected between the power supply line Vdd and the transistor 26. A control terminal of the transistor 25 is connected to the charge holding section 22. The transistor 25 outputs a voltage corresponding to the amount of charge held by the charge holding section 22, that is, the amount of charge generated in the photoelectric conversion section 21.

The transistor 26 is a selection transistor that is connected between the transistor 25 and the signal line VL and causes the output voltage of the transistor 25 to selectively appear in the signal line VL. The voltage appearing in the signal line VL is a pixel signal. A control terminal of the transistor 26 is connected to the signal line HL SEL. On and off of the transistor 26 are controlled by a control signal from the signal line HL SEL.

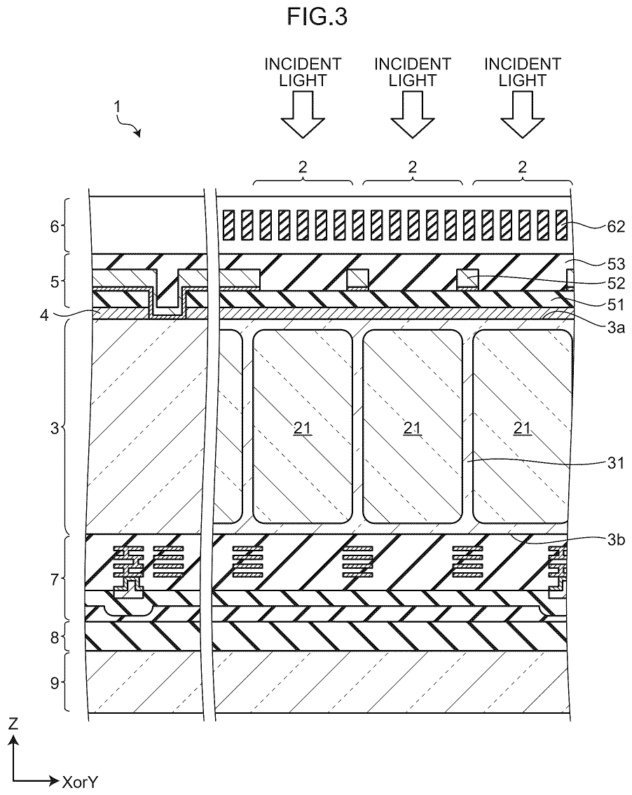

FIG. 3 is a diagram illustrating an example of a schematic configuration of the pixel array section 1. A cross section of a part of the pixel array section 1 in a side view (as viewed in the X-axis direction or the Y-axis direction) is schematically illustrated. The pixel array section 1 includes a semiconductor substrate 3, a fixed charge film 4, an insulating layer 5, an optical layer 6, a wiring layer 7, an insulating layer 8, and a support substrate 9. A plane direction of the substrate, the film, and the layer corresponds to an XY planar direction (an X-axis direction and a Y-axis direction), and a thickness direction corresponds to a Z-axis direction. The Z-axis positive direction may be referred to as an upward direction or the like. The Z-axis negative direction may be referred to as a downward direction or the like. Note that the layer and the film may be read as each other within a range without contradiction.

Note that a portion illustrated on the right side of FIG. 3 is an effective region in which the pixel 2 including the photoelectric conversion section 21 is arranged. A portion illustrated on the left side of FIG. 3 is an ineffective region (a region outside the effective region) where such a pixel 2 is not arranged. The light incident on the pixel array section 1 is referred to as incident light, and is schematically indicated by an outlined arrow. It is assumed that the incident light travels downward (Z-axis negative direction).

At least a part of the components of the circuit of the pixel 2 is formed on the semiconductor substrate 3. Examples of the material of the semiconductor substrate 3 include Si, SiGe, and InGaAs. As a component formed on the semiconductor substrate 3, the photoelectric conversion section 21 is illustrated in FIG. 3.

The upper surface (the surface on the Z-axis positive direction side) of the semiconductor substrate 3 is referred to as an upper surface 3a in the drawing. The lower surface (the surface on the Z-axis negative direction side) of the semiconductor substrate 3 is referred to as a lower surface 3b in the drawing. The light incident on the pixel array section 1 enters the semiconductor substrate 3 from the upper surface 3a of the semiconductor substrate 3 and reaches the photoelectric conversion section 21. Note that, since the wiring layer 7 to be described later is provided on the lower surface 3b of the semiconductor substrate 3, it can be said that the lower surface 3b of the semiconductor substrate 3 is the front surface of the semiconductor substrate 3 and the upper surface 3a of the semiconductor substrate 3 is the back surface of the semiconductor substrate 3. The photodetector 100 (FIG. 1) can also be referred to as a back-illuminated photodetector, an imaging apparatus, or the like.

The photoelectric conversion section 21 will be further described. In this example, the photoelectric conversion section 21 is formed over substantially the entire region in the thickness direction (Z-axis direction) of the semiconductor substrate 3. The photoelectric conversion section 21 is, for example, a pn junction type photodiode (PD) including an n-type semiconductor region and a p-type semiconductor region formed so as to face both the upper surface 3a and the lower surface 3b of the semiconductor substrate 3.

The p-type semiconductor region also serves as a hole charge accumulation region for suppressing dark current. Each pixel 2 is separated by a separation region 31. The separation region 31 is formed of a p-type semiconductor region and is grounded, for example. The transistors 23 to 26 described above with reference to FIG. 2 are configured by forming an n-type source region and a drain region in a p-type semiconductor well region formed on the lower surface 3b side of the semiconductor substrate 3, and forming a gate electrode on the lower surface 3b of the semiconductor substrate 3 between the source region and the drain region via a gate insulating film.

On the upper surface 3a of the semiconductor substrate 3, the fixed charge film 4, the insulating layer 5, and the optical layer 6 are provided in this order. It can also be said that the upper surface 3a of the semiconductor substrate 3 faces the fixed charge film 4, the insulating layer 5, and the optical layer 6.

The fixed charge film 4 has a negative fixed charge due to a dipole of oxygen and plays a role of enhancing pinning. An example of the material of the fixed charge film 4 is an oxide or a nitride. The oxide or nitride may contain at least one of Hf, Al, zirconium, Ta, and Ti. In addition, the oxide or nitride may contain at least one of lanthanum, cerium, neodymium, promethium, samarium, europium, gadolinium, terbium, dysprosium, holmium, thulium, ytterbium, lutetium, and yttrium. Another example of the material of the fixed charge film 4 is hafnium oxynitride, aluminum oxynitride, or the like. Silicon or nitrogen may be added to the fixed charge film 4 in an amount that does not impair insulating properties. Heat resistance and the like can be improved. The fixed charge film 4 may be configured to also serve as a reflection suppressing film for the semiconductor substrate 3 such as a Si substrate having a high refractive index by controlling the film thickness or laminating multiple layers.

The insulating layer 5 insulates the semiconductor substrate 3 and the fixed charge film 4 from the optical layer 6, and protects the semiconductor substrate 3 and the fixed charge film 4. In this example, the insulating layer 5 includes an insulating film 51, a light shielding film 52, and an insulating film 53. An example of the material of the insulating film 51 and the insulating film 53 is SiO₂ or the like.

The insulating film 51 is also a base layer for providing the light shielding film 52 thereon.

The light shielding film 52 is provided on the insulating film 51. The light shielding film 52 is arranged in a boundary region between (the photoelectric conversion sections 21 of) the adjacent pixels 2, and shields stray light leaking from the adjacent pixels 2. The light shielding film 52 includes a material that shields light. A material having a strong light shielding property and capable of being accurately processed by microfabrication, for example, etching may be used. Examples of the material include metal materials such as Al, W, and copper. The light shielding film 52 may be formed of a metal film containing such a metal material. In addition, silver, gold, platinum, Mo, Cr, Ti, nickel, iron, tellurium, and the like, an alloy containing these, and the like may be used as the material of the light shielding film 52. A plurality of these materials may be laminated. In order to enhance adhesion to the underlying insulating film 51, a barrier metal, for example, Ti, Ta, W, Co, Mo, an alloy thereof, a nitride thereof, an oxide thereof, or a carbide thereof may be provided under the light shielding film 52.

The light shielding film 52 may also serve as light shielding for a pixel for determining an optical black level or may also serve as light shielding for preventing noise to a peripheral circuit region. The light shielding film 52 is desirably grounded so as not to be destroyed by plasma damage due to accumulated charges during processing. The ground structure may be formed in the pixel array, but may be grounded in a region outside the effective region of the pixel 2 as illustrated on the left side of FIG. 3 after all the conductors are electrically connected.

The insulating film 53 is provided so as to cover the insulating film 51 and the light shielding film 52. The insulating film 53 also plays a role of planarization.

In this example, the optical layer 6 is provided so as to cover the photoelectric conversion section 21 of the semiconductor substrate 3 with the fixed charge film 4 and the insulating layer 5 interposed therebetween. As components of the optical layer 6, a plurality of pillars 62 are illustrated in FIG. 3. Details of the optical layer 6 will be described later.

On the lower surface 3b of the semiconductor substrate 3, the wiring layer 7, the insulating layer 8, and the support substrate 9 are provided in this order. It can also be said that the lower surface 3b of the semiconductor substrate 3 faces the wiring layer 7, the insulating layer 8, and the support substrate 9.

The wiring layer 7 transmits an image signal generated by the pixel 2. Furthermore, the wiring layer 7 further transmits a signal applied to the circuit of the pixel 2. Specifically, the wiring layer 7 constitutes the signal line HL and the power supply line Vdd (FIGS. 1 and 2). The wiring layer 7 and the circuit are connected by a via plug. In addition, the wiring layer 7 includes multiple layers, and the layers of each wiring layer are also connected by a via plug. An example of the material of the wiring layer 7 is a metal material such as Al or Cu. Examples of the material of the via plug include metal materials such as W and Cu. For insulation of the wiring layer 7, for example, a silicon oxide film or the like is used.

The insulating layer 8 insulates the wiring layer 7 from the support substrate 9. Various known materials may be used.

The support substrate 9 reinforces and supports the semiconductor substrate 3 and the like in the manufacturing process of the pixel array section 1. An example of the material of the support substrate 9 is silicon or the like. The support substrate 9 may be bonded to the semiconductor substrate 3 by plasma bonding or an adhesive material. The support substrate 9 may be configured to include a logic circuit. By forming the connection vias between the substrates, various peripheral circuit functions can be stacked vertically, and the chip size can be reduced.

The optical layer 6 will be further described. The optical layer 6 controls a phase and the like of the incident light. The optical layer 6 can also be referred to as a light control section, an optical phase control section, or the like.

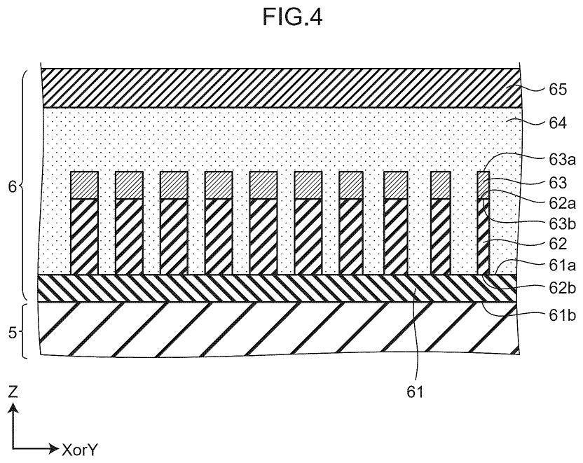

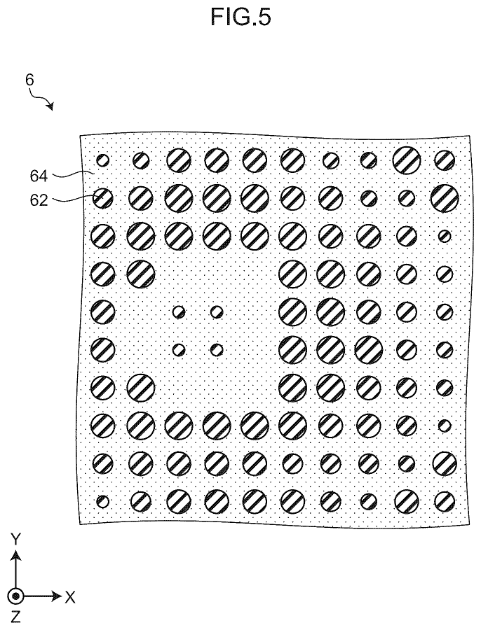

FIGS. 4 and 5 are diagrams illustrating an example of a schematic configuration of the optical layer 6. Note that FIG. 5 schematically illustrates a cross section of a portion including the pillars 62 of the optical layer 6 in plan view (as viewed in the Z-axis direction).

The optical layer 6 includes a reflection suppressing film 61, a plurality of pillars 62, a reflection suppressing film 63, a filler 64, and a protective film 65. The upper surface and the lower surface of the reflection suppressing film 61 are referred to as an upper surface 61a and a lower surface 61b in the drawing. The upper surface and the lower surface of the pillar 62 are referred to as an upper surface 62a and a lower surface 62b in the drawing. The upper surface and the lower surface of the reflection suppressing film 63 are referred to as an upper surface 63a and a lower surface 63b in the drawing.

The reflection suppressing film 61 is provided between the pillar 62 and the insulating layer 5, more specifically, on the insulating layer 5 and on the lower surface 62b of the pillar 62. The upper surface 61a of the reflection suppressing film 61 is in surface contact with the lower surface 62b of the pillar 62 and the filler 64. This surface serves as a refractive index boundary surface between the reflection suppressing film 61 and the pillar 62, and also serves as a refractive index boundary surface between the reflection suppressing film 61 and the filler 64.

The reflection suppressing film 61 suppresses light reflection on the lower surface 62b of the pillar 62 and the vicinity thereof. For example, the reflection suppressing film 61 has a refractive index between the refractive index of the insulating layer 5 and the refractive index of the pillar 62. Assuming that a wavelength of light to be detected in a medium is λ, the reflection suppressing film 61 may have a thickness of λ/4n (n is a refractive index of the medium) or an integral multiple thereof. By providing such a reflection suppressing film 61, light reflection on the lower surface 62b of the pillar 62 and the vicinity thereof can be suppressed. An example of the material of the reflection suppressing film 61 is SiN or the like.

The pillar 62 is a fine structure having a dimension shorter than the wavelength of the incident light, more specifically, the detection target light. The pillar 62 is processed to have a columnar shape or a shape based on the columnar shape, and extends in the thickness direction of the optical layer 6. An example of the material of the pillar 62 is amorphous silicon or the like.

The plurality of pillars 62 are arranged side by side at intervals, for example, in the plane direction of the optical layer 6 so as to guide light to be detected among the incident light to the photoelectric conversion section 21 (FIG. 3). The light to be detected may be visible light or invisible light. Examples of the visible light include red light, green light, and blue light. Examples of the invisible light include infrared light (IR) and the like, and more specifically may be near-infrared light (NIR).

The plurality of pillars 62 imparts an optical function to the optical layer 6. An example of the optical function is a function of controlling the direction of light, more specifically, a prism function, a lens function, and the like. The prism function is a function of separating light included in incident light for each wavelength and guiding (directing) light to be detected among the light to the photoelectric conversion section 21, and can also be called a splitter function, a color separation function, a filter function, or the like. The lens function is a function of condensing light on the photoelectric conversion section 21 (condensing function).

Each pillar 62 is designed to give a local phase difference to the light passing through the optical layer 6. Examples of the design of the pillar 62 include a design of a dimension of the pillar 62, a design of a shape of the pillar 62, a design of an arrangement of the pillar 62, and the like. Examples of the dimensions of the pillar 62 include the width of the pillar 62 (length in X-axis direction, length in Y-axis direction), the height of the pillar 62 (the length in the Z-axis direction), and the like. Examples of the shape of the pillar 62 include a shape when the pillar 62 is viewed in plan view (when viewed in the Z-axis direction), a shape when the pillar 62 is viewed in a side view (when viewed in X-axis direction and Y-axis direction), and the like. The shape may be a cross-sectional shape. The arrangement of the pillars 62 is a planar layout of the pillars 62 or the like, and includes, for example, an interval (pillar pitch) between adjacent pillars 62.

For example, in a case where the pillar 62 has a refractive index higher than the refractive index of its peripheral region (for example, the refractive index of the filler 64), the effective refractive index of a portion where the proportion occupied by the pillar 62 is large becomes high, and the effective refractive index of a portion where the proportion occupied by the pillar 62 is small becomes low. A phase of light passing through a portion having a high effective refractive index is delayed from a phase of light passing through a portion having a low effective refractive index. The direction of the light can be controlled by making the phase delay amount of the light different.

The reflection suppressing film 63 is provided on the upper surface 62a of the pillar 62. The lower surface 63b of the reflection suppressing film 63 is in surface contact with the upper surface 62a of the pillar 62. This surface serves as a refractive index boundary surface between the reflection suppressing film 63 and the pillar 62.

The reflection suppressing film 63 suppresses light reflection on the upper surface 62a of the pillar 62 and the vicinity thereof. For example, the reflection suppressing film 63 has a refractive index between the refractive index of the pillar 62 and the refractive index of the upper region (in this example, the filler 64) of the reflection suppressing film 63. The reflection suppressing film 63 may have a thickness of λ/4n (n is a refractive index of the medium) or an integral multiple thereof. By providing such a reflection suppressing film 63, light reflection on the upper surface 62a of the pillar 62 and the vicinity thereof can be suppressed. An example of the material of the reflection suppressing film 63 is SiN or the like. The reflection suppressing film 63 may be a low temperature oxide film (LTO film, for example, a silicon oxide film) or the like.

The filler 64 is provided so as to fill a gap between the pillars 62, and is provided so as to cover the reflection suppressing film 61, the pillars 62, and the reflection suppressing film 63. Pillar collapse (collapse of pillars 62) can be suppressed, and tape residue in the assembly process can be suppressed. An example of the material of the filler 64 is resin or the like. The refractive index of the filler 64 may be lower than the refractive index of each of the reflection suppressing film 61, the pillar 62, and the reflection suppressing film 63. The filler 64 is, for example, in surface contact with the upper surface 63a of the reflection suppressing film 63, and this surface becomes a refractive index boundary surface between the filler 64 and the reflection suppressing film 63.

The protective film 65 is provided on the filler 64. For example, it is possible to avoid the filler 64 from being damaged when the PAD resist of the PAD opening is peeled off in the subsequent process. The material of the protective film 65 may be an inorganic material such as SIO2. The protective film 65 in this case can also be referred to as an inorganic protective film.

The thickness of the portion of the filler 64 located between the pillar 62 (more specifically, the reflection suppressing film 63) and the protective film 65 and the thickness of the protective film 65 may be designed such that the reflected waves cancel each other as a whole using, for example, the Fresne1 coefficient method or the like in consideration of the refractive index and the wavelength of the light to be detected.

Note that the filler 64 may be omitted. In this case, for example, the peripheral materials of the reflection suppressing film 61, the pillars 62, and the reflection suppressing film 63 may be air (air region). As long as there is no contradiction, the filler 64 may be appropriately read as a peripheral material, air (air region), or the like. Further, the protective film 65 may not be provided.

In the optical layer 6 having the configuration described above, since the pillars 62 are fine structures, there is a possibility that pillar collapse occurs. A specific technique for suppressing pillar collapse will be described as first to fourth embodiments to be described later.

### 1. First Embodiment

In the first embodiment, the pillar collapse is suppressed by devising the shape of the pillar 62.

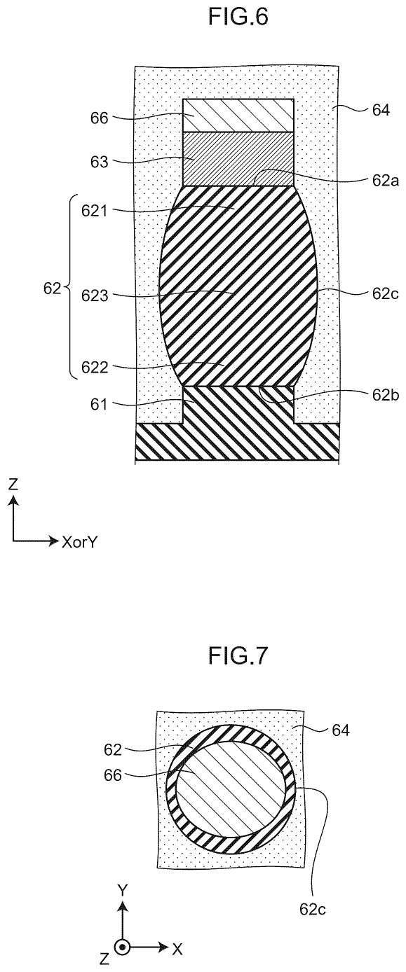

FIGS. 6 and 7 are diagrams illustrating an example of a schematic configuration of the pillar 62 and its peripheral structure. FIG. 6 schematically illustrates a cross section in a side view (as viewed in the X-axis direction or the Y-axis direction). FIG. 7 schematically illustrates a planar layout in plan view (as viewed in the Z-axis negative direction). In this example, the reflection suppressing film 63 and the LTO film 66 are provided so as to cover the upper surface 62a of the pillar 62. Specifically, the reflection suppressing film 63 is provided on the upper surface 62a of the pillar 62, and the LTO film 66 (for example, a silicon oxide film) is further provided thereon.

The side surface of the pillar 62 is referred to as a side surface 62c in the drawing. At least a part of the side surface 62c has a curved surface bulging toward the outside of the pillar 62. It can also be said that the side surface portion of the pillar 62 has a bulge. Specifically, the pillar 62 includes an upper end portion 621, a lower end portion 622, and an intermediate portion 623.

The upper end portion 621 is a portion having the upper surface 62a of the pillar 62. The lower end portion 622 is a portion having the lower surface 62b of the pillar 62. The intermediate portion 623 is a portion located between the upper end portion 621 and the lower end portion 622. At least a part of the intermediate portion 623 has a width larger than the width (length in the XY planar direction) of either the upper end portion 621 or the lower end portion 622. When viewed in the pillar height direction (Z-axis direction), at least a part of the intermediate portion 623 has a cross-sectional area larger than the area of any of the upper surface 62a and the lower surface 62b of the pillar 62.

When the pillar 62 is viewed in plan view, the reflection suppressing film 63 is located inside the pillar 62. Similarly, the LTO film 66 is located inside the pillar 62. For example, as illustrated in FIG. 7, when the pillar 62 is viewed from above (viewed in the Z-axis negative direction), a part of the pillar 62 appears outside the LTO film 66.

The filler 64 is provided so as to fill the space between the plurality of pillars 62. In this example, the filler 64 is provided so as to fill the space between the adjacent pillars 62 and cover the reflection suppressing film 61, the pillars 62, the reflection suppressing film 63, and the filler 64. The filler 64 is in contact with at least the side surface 62c of the pillar 62. Since the side surface 62c of the pillar 62 bulges outward, for example, the filler 64 is easily caught by the pillar 62 as compared with a case where the side surface 62c is straight, and the filler 64 is less likely to peel off from the pillar 62 (also referred to as a hook effect or the like). This increases the possibility of suppressing the pillar collapse.

In addition, the fact that the cross-sectional area of the intermediate portion 623 of the pillar 62 is larger than the upper surface 62a means that a thickness (width or cross-sectional area) exceeding the limit of the lithography technique is given to the pillar 62. The effective line width can be adjusted by thickening the pillars 62.

In one embodiment, the side surface 62c of the pillar 62 may further have a curved surface recessed inward. This will be described with reference to FIG. 8.

FIG. 8 is a diagram illustrating an example of the pillar 62 and its peripheral structure. The pillar 62 includes two intermediate portions 623. A first intermediate portion 623 is referred to as an intermediate portion 623-1 in the drawing. A second intermediate portion 623 is referred to as an intermediate portion 623-2 in the drawing.

As described above, the intermediate portion 623-1 has a width larger than the width of each of the upper end portion 621 and the lower end portion 622, and has a cross-sectional area larger than the area of each of the upper surface 62a and the lower surface 62b of the pillar 62. The intermediate portion 623-2 may have a width smaller than a width of at least one of the upper end portion 621 and the lower end portion 622 (lower end portion 622 in this example), and may have a cross-sectional area smaller than an area of at least one of the upper surface 62a and the lower surface 62b of the pillar 62 (lower surface 62b in this example).

Since the side surface 62c of the pillar 62 has not only a curved surface bulging outward but also a curved surface recessed inward, the filler 64 is more easily caught on the pillar 62. The filler 64 is further peeled off from the pillar 62, and the effect of suppressing the pillar collapse is further enhanced.

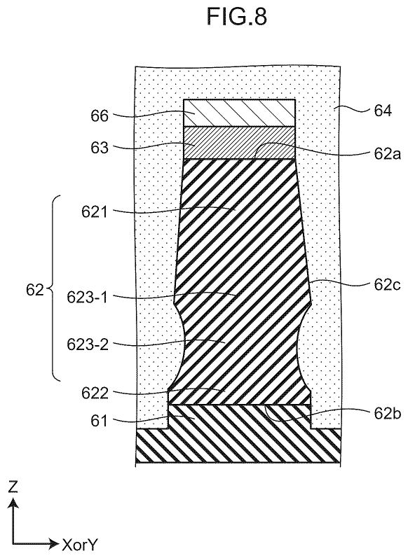

FIGS. 9 to 13 are diagrams illustrating an example of a manufacturing method. The material of the reflection suppressing film 61 is referred to as a reflection suppressing film material 61m. The material of the pillar 62 is referred to as a pillar material 62m. The material of the reflection suppressing film 63 is referred to as a reflection suppressing film material 63m. The material of the LTO film 66 is referred to as an LTO film material 66m.

As illustrated in FIG. 9, the pillar material 62m is formed on the reflection suppressing film material 61m. The reflection suppressing film material 61m is, for example, SiN and functions as a stopper. The pillar material 62m is, for example, amorphous silicon having a higher refractive index.

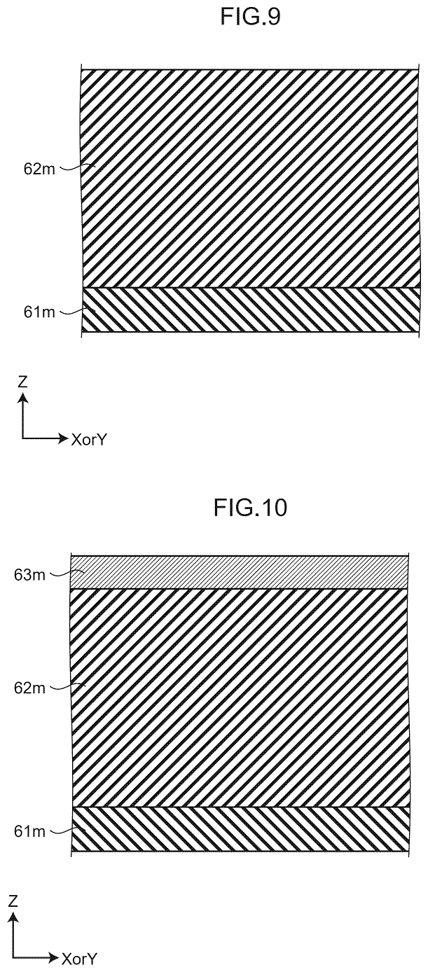

As illustrated in FIG. 10, the reflection suppressing film material 63m is formed on the pillar material 62m.

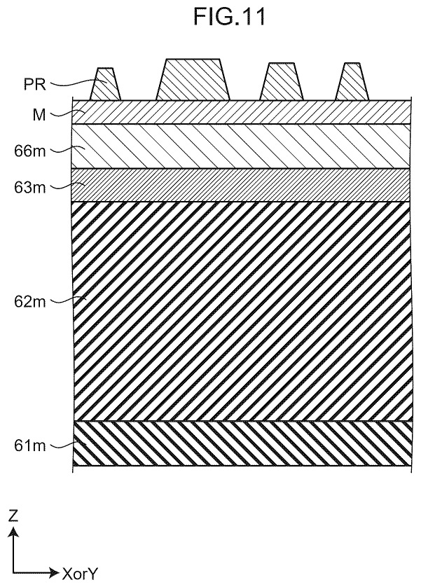

As illustrated in FIG. 11, an LTO film material 66m is formed on the reflection suppressing film material 63m, and a mask M is further provided thereon. The mask M may have a laminated structure in which a plurality of masks are laminated. The photoresist PR (for example, ArF resist) having a pattern matching the pillar shape is formed on the mask M. In this example, the photoresist PR has a tapered shape in which the cross-sectional area (area as viewed in the Z-axis direction) decreases with distance from the mask M.

As illustrated in FIG. 12, the pillar material 62m, the reflection suppressing film material 63m, and the LTO film material 66m are processed by dry etching. As a result, the pillar 62 including the intermediate portion 623 (in this example, the intermediate portion 623-1 and the intermediate portion 623-2) and the reflection suppressing film 63 and the LTO film 66 sequentially provided thereon are obtained.

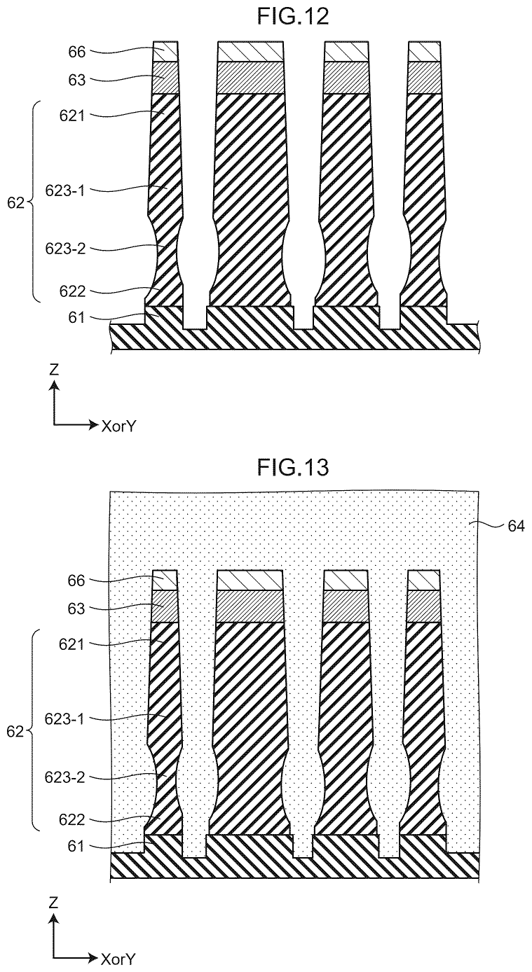

As illustrated in FIG. 13, the filler 64 is provided so as to fill the space between the plurality of pillars 62, more specifically, so as to cover the reflection suppressing film 61, the pillars 62, the reflection suppressing film 63, and the filler 64.

### <Section Summary>

The technology according to the first embodiment described above is specified as follows, for example. One of the disclosed techniques is the photodetector 100. As described with reference to FIGS. 1 to 8 and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the filler 64 provided so as to fill a space between the plurality of pillars 62. The side surface 62c of the pillar 62 has a curved surface bulging toward the outside of the pillar 62. As a result, the filler 64 is easily caught by the pillar 62, and the filler 64 is hardly peeled off from the pillar 62. Therefore, pillar collapse can be suppressed.

As described with reference to FIGS. 6, 7, and the like, the pillar 62 may include the upper end portion 621 having the upper surface 62a of the pillar 62, the lower end portion 622 having the lower surface 62b of the pillar 62, and the intermediate portion 623 located between the upper end portion 621 and the lower end portion 622 and having a width larger than the width of any of the upper end portion 621 and the lower end portion 622. The intermediate portion 623 may have a cross-sectional area larger than any area of the upper surface 62a and the lower surface 62b. The optical layer 6 includes a film (reflection suppressing film 63 and LTO film 66) provided to cover the upper surface 62a of the pillar 62, and the film may be located inside the pillar 62 when the pillar 62 is viewed in plan view (when viewed in the Z-axis negative direction). For example, by using the pillar 62 having such a configuration, the pillar collapse can be suppressed.

As described with reference to FIG. 8 and the like, the side surface 62c of the pillar 62 may further have a curved surface recessed toward the inside of the pillar 62. The filler 64 is more easily caught by the pillar 62, and the pillar collapse can be further suppressed.

### 2. Second Embodiment

In the second embodiment, the pillar collapse is suppressed by devising the shape of the reflection suppressing film 61.

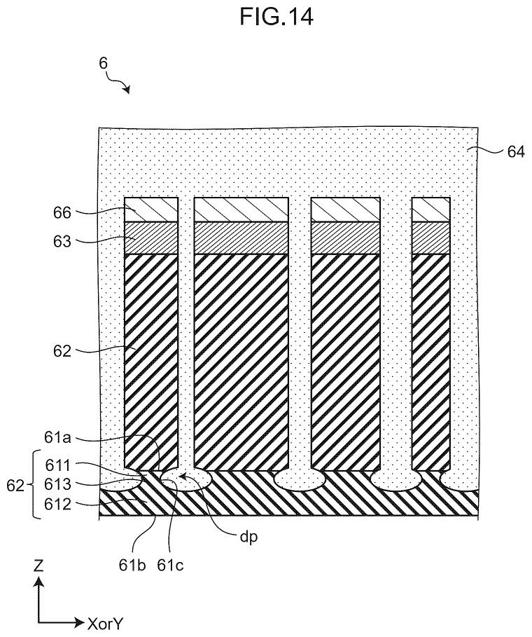

FIG. 14 is a diagram illustrating an example of a schematic configuration of the optical layer 6. The reflection suppressing film 61 includes a plurality of upper end portions 611, a lower end portion 612, and a plurality of intermediate portions 613 corresponding to the plurality of upper end portions 611. Each of the plurality of upper end portions 611 is located on the lower surface 62b of the corresponding pillar 62 and is a portion having the upper surface 61a of the reflection suppressing film 61. The lower end portion 612 is a portion having the lower surface 61b of the reflection suppressing film 61. Each of the plurality of intermediate portions 613 is a portion located between the corresponding upper end portion 611 and lower end portion 612.

A side surface of the reflection suppressing film 61, more specifically, a side surface of a portion of the upper end portion 611 and the intermediate portion 613 is referred to as a side surface 61c in the drawing. At least a part of the side surface 61c has a curved surface recessed toward the inside of the reflection suppressing film 61. It can also be said that the side surface portion of the reflection suppressing film 61 has a dent.

The intermediate portion 613 has a width smaller than the width of any of the upper end portion 611 and the lower end portion 612. The intermediate portion 613 has a cross-sectional area smaller than any area of the upper surface 61a and the lower surface 61b of the reflection suppressing film 61.

A depression dp is formed at an interface between the upper surface 61a of the reflection suppressing film 61 and the lower surface 62b of the pillar 62. The filler 64 is provided so as to fill the space between the plurality of pillars 62 and cover the reflection suppressing film 61. The depression dp is filled with the filler 64. The filler 64 is easily caught by the pillar 62, and the filler 64 is hardly peeled off from the pillar 62. This increases the possibility of suppressing the pillar collapse.

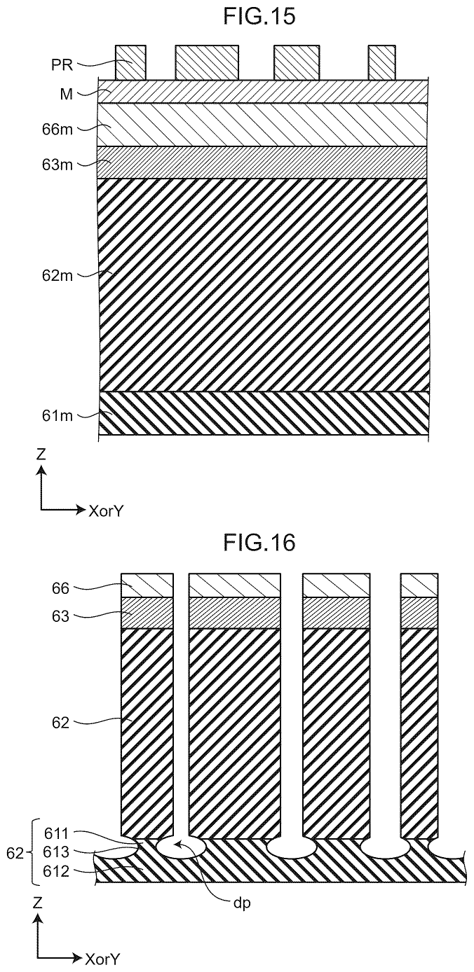

FIGS. 15 and 16 are diagrams illustrating an example of a manufacturing method. As a premise, it is assumed that the process of FIG. 10 described in the first embodiment has been completed.

As illustrated in FIG. 15, an LTO film material 66m is formed on the reflection suppressing film material 63m, and a mask M is further provided thereon. The photoresist PR (for example, ArF resist) having a pattern matching the pillar shape is formed on the mask M.

As illustrated in FIG. 16, the pillar material 62m, the reflection suppressing film material 63m, and the LTO film material 66m are processed by dry etching. The depression dp is generated during dry etching. As a result, the reflection suppressing film 61 including the plurality of upper end portions 611, the lower end portion 612, and the plurality of intermediate portions 613, and the plurality of pillars 62, the reflection suppressing film 63, and the LTO film 66, each of which is sequentially provided on the corresponding upper end portion 611, are obtained.

Thereafter, the configuration of FIG. 14 described above is obtained by providing the filler 64.

### <Section Summary>

The technology according to the second embodiment described above is specified as follows, for example. One of the disclosed techniques is the photodetector 100. As described with reference to FIGS. 1 to 5, 14, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, the reflection suppressing film 61 provided on the lower surface 62b of the pillar 62, and the filler 64 provided so as to fill a space between the plurality of pillars and cover the reflection suppressing film 61. The reflection suppressing film 61 is located on the lower surface 62b of the pillar 62 and includes the upper end portion 611 having the upper surface 61a of the reflection suppressing film 61, the lower end portion 612 having the lower surface 61b of the reflection suppressing film 61, and the intermediate portion 613 located between the upper end portion 611 and the lower end portion 612 and having a width smaller than the width of the upper end portion 611. As a result, the filler 64 is easily caught by the pillar 62, and the filler 64 is hardly peeled off from the pillar 62. Therefore, pillar collapse can be suppressed.

As described with reference to FIG. 14 and the like, the side surface 61c of the reflection suppressing film 61 may have a curved surface recessed inward. The depression dp may be formed at the interface between the upper surface 61a of the reflection suppressing film 61 and the lower surface 62b of the pillar 62, and the depression dp may be filled with the filler 64. For example, with such a configuration, the filler 64 can be easily caught by the pillar 62, and the pillar collapse can be suppressed.

### 3. Third Embodiment

In the third embodiment, by covering the side surface 62c of the pillar 62 with a film, the pillar collapse is suppressed.

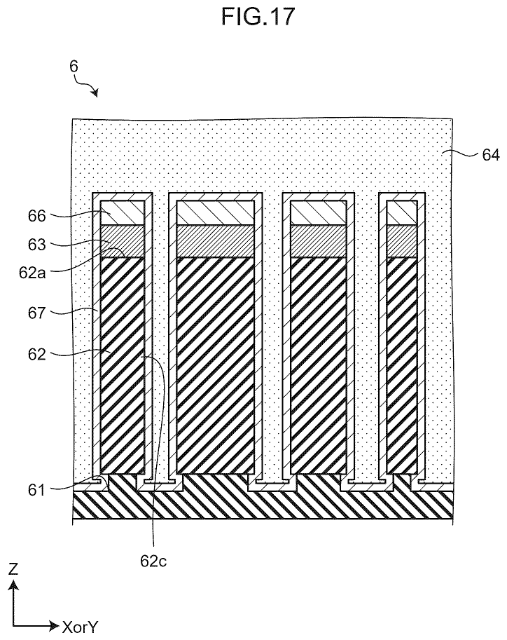

FIG. 17 is a diagram illustrating an example of a schematic configuration of the optical layer 6. The optical layer 6 includes a film 67. The film 67 is provided so as to cover at least the side surface 62c of the pillar 62. In this example, film 67 is provided on the side surface 62c of the pillar 62. The film 67 may be provided to cover the upper surface 62a of the pillar 62. In this example, the film 67 is provided on the upper surface of the LTO film 66 so as to cover the upper surface 62a of the pillar 62 with the reflection suppressing film 63 and the LTO film 66 interposed therebetween. The filler 64 is provided so as to fill the space between the plurality of pillars 62 and cover the film 67.

The film 67 may be, for example, a transparent insulating film. Since the pillar 62 is covered with the film 67, the pillar 62 is less likely to fall than when not. Therefore, pillar collapse can be suppressed.

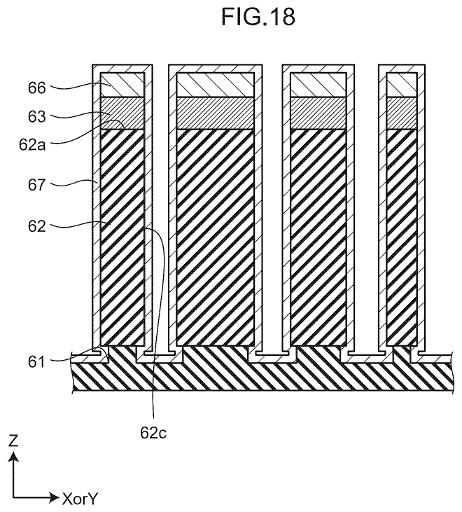

FIG. 18 is a diagram illustrating an example of a manufacturing method. As a premise, it is assumed that the process of FIG. 15 described in the second embodiment is completed. As illustrated in FIG. 18, the pillar material 62m, the reflection suppressing film material 63m, and the LTO film material 66m are processed by dry etching to obtain the pillar 62, the reflection suppressing film 63, and the LTO film 66. The film 67 is formed so as to cover them using, for example, atomic layer deposition (ALD). By providing the filler 64 so as to fill the space between the plurality of pillars 62 and cover the film 67, the above-described configuration of FIG. 17 is obtained.

Further technical significance of covering the pillar 62 with the film 67 will be described. First, since the pillar collapse can be suppressed as described above, the design rule of the pillar 62 can be relaxed accordingly. For example, a design of pillars 62 having a smaller width (which may be a cross-sectional area) is enabled. Accordingly, the difference in effective refractive index between each pillar 62 and its peripheral region can be increased, and desired optical characteristics can be easily obtained. Furthermore, the film 67 may be used as a reflection suppressing film.

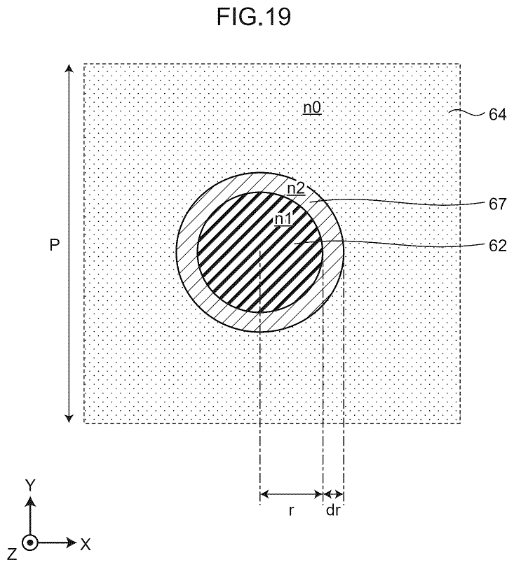

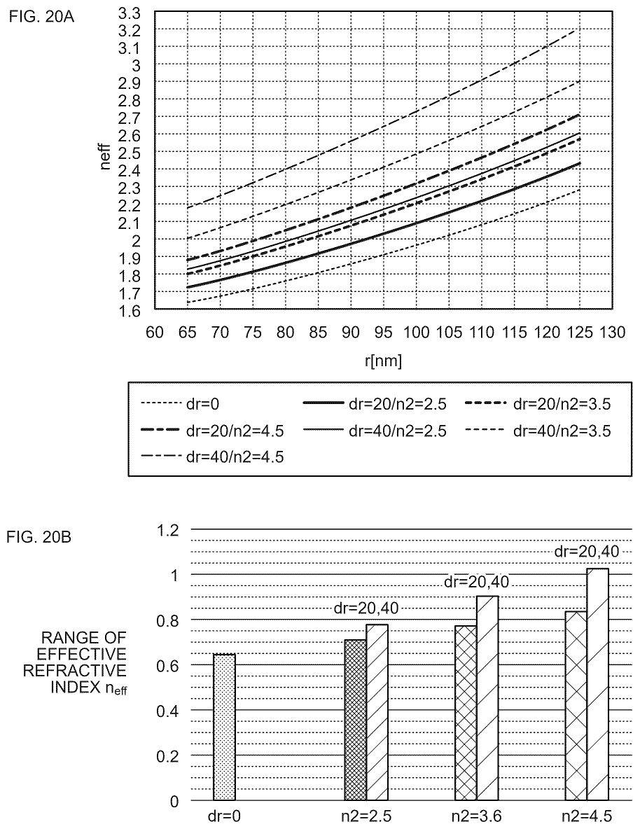

The relationship between covering the pillar 62 with the film 67 and the effective refractive index will be described with reference to FIGS. 19 and 20.

FIGS. 19 and 20 are diagrams illustrating examples of the effective refractive index. FIG. 19 schematically illustrates the pillar 62 and the film 67 in plan view (as viewed in the Z-axis direction). In this example, the pillar 62 has a circular cross-sectional shape. The film 67 has an annular cross-sectional shape with the pillar 62 inside. The pillar pitch is referred to as a pillar pitch P in the drawing. The radius of the pillar 62 is referred to as a radius r in the drawing. The thickness of the film 67 is referred to as a thickness dr in the drawing.

The refractive index of the pillar 62 is referred to as a refractive index n1. The refractive index of the film 67 is referred to as a refractive index n2. The refractive index of the filler 64 is referred to as a refractive index n0. Assuming that the effective refractive index within the range of the pillar pitch P is the effective refractive index n_{eff}, the effective refractive index n_{eff} is expressed by the following Formula (1). As will be appreciated, the larger the original diameter (radius r of the pillars 62), the higher the effective refractive index n_{eff}.

$${n}_{eff} ∼ \frac{{n}_{0}}{{P}^{2}} \{ {P}^{2} - {π ( r + dr )}^{2} \} + \frac{{n}_{1}}{{P}^{2}} π {r}^{2} + \frac{{n}_{2}}{{P}^{2}} π ( 2 rdr + {dr}^{2} ) \qquad ( 1 )$$

In addition, the inner second moment of area Iᵢₙₙₑᵣ and the outer second moment of area Iₒᵤₜₑᵣ are expressed by the following Formulas (2) and (3). As can be understood, the second moment of area increases even when the original diameter is small.

$${I}_{inner} = \frac{π {r}^{4}}{4} \qquad ( 2 )$$

$${I}_{outer} = \frac{π [ {( r + dr )}^{4} - {r}^{4} ]}{4} \qquad ( 3 )$$

In (A) of FIG. 20, an example of the effective refractive index n_{eff} with respect to the radius r is illustrated by a graph. In (B) of FIG. 20, an example of the range of the effective refractive index n_{eff} is illustrated by a graph. The refractive index no of the filler 64 is 1.4. The refractive index n1 of the pillar 62 is 3.6. The pillar pitch P is 350 nm. Note that the thickness dr=0 means that there is no film 67. As illustrated in (A) of FIG. 20, the effective refractive index n_{eff} increases as the radius r of the pillar 62 increases. As illustrated in (B) of FIG. 20, the range of the effective refractive index n_{eff} can be enlarged by increasing the thickness dr of the film 67 or increasing the refractive index n2.

Various designs are possible. Some examples are described as Examples 1 to 12 below.

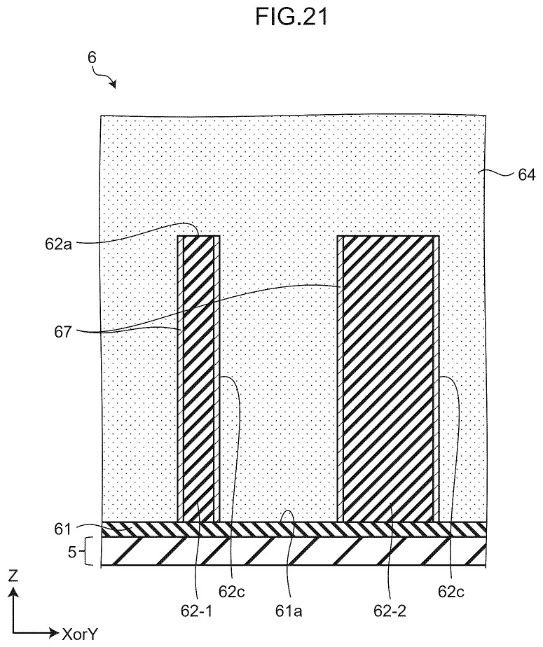

First, a configuration common to Examples 1 to 3 will be described with reference to FIG. 21.

FIG. 21 is a diagram illustrating an example of a schematic configuration of the optical layer 6. Two adjacent pillars 62 among the plurality of pillars 62 are exemplified. Among them, a pillar 62 having a relatively small width is referred to as a pillar 62-1 in the drawing. A pillar 62 having a relatively large width is referred to as a pillar 62-2 in the drawing. In a case where they are not particularly distinguished, they are simply referred to as pillars 62.

The reflection suppressing film 63 and the LTO film 66 as described above are not provided on the upper surface 62a of the pillar 62. The film 67 is provided on the side surface 62c so as to cover the side surface 62c of the pillar 62. The film 67 does not cover the upper surface 62a of the pillar 62, and does not cover the upper surface 61a of the reflection suppressing film 61.

An example of a manufacturing method will be described. After the pillar 62 is processed, the film 67 having high transparency is formed on the side surface 62c of the pillar 62. Thereafter, the film 67 is etched back to remove the film 67 laminated on the upper surface 62a of the pillar 62 and the upper surface 61a of the reflection suppressing film 61. Thereafter, the filler 64 is formed so as to cover the pillar 62. There may be no filler 64, and the portion may be a void (air region).

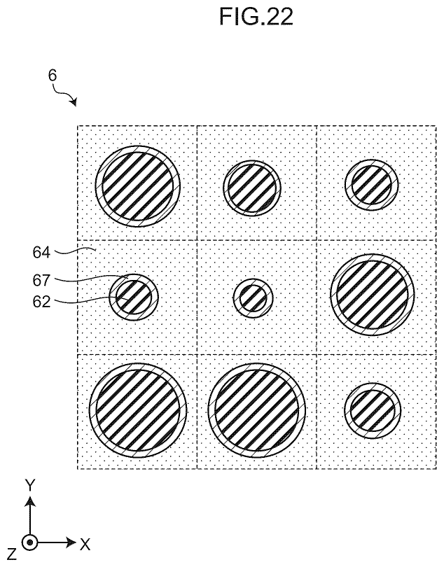

FIG. 22 is a diagram illustrating an example of a planar layout of the pillar 62. Various pillars 62 having different widths are arranged side by side. Each pillar 62 is covered by the film 67.

In the configurations illustrated in FIGS. 21 and 22 described above, various combinations of materials and refractive indexes of the pillars 62, the film 67, and the filler 64 are possible. Specific examples will be described as Examples 1 to 3.

### Example 1

In Example 1, the film 67 has a refractive index higher than the refractive index of the filler 64. More specifically, the refractive index n2 of the film 67 is the highest, the refractive index no of the filler 64 is the lowest, and the refractive index n1 of the pillar 62 is a value therebetween (n2 >n1 >n0).

An example of the material and the refractive index in a case where the wavelength of the light to be detected is 940 nm is as follows.
Pillar 62: amorphous silicon (a-Si), refractive index n1=3.6
Film 67: germanium (Ge), refractive index n2=4.5 Filler 64: polymer resin, refractive index n0=1.4

An example of a material and a refractive index in a case where light to be detected is visible light (red light, green light, and blue light) is as follows.
Pillar 62: silicon nitride (Si₃N₄), refractive index n1=2.01 to 2.08
Film 67: titanium oxide TiO₂, refractive index n2=2.56 to 2.87
Filler 64: none (air region). Refractive index n0=1.0

### Example 2

In Example 2, the film 67 has the same refractive index as the refractive index of the pillars 62. More specifically, the refractive index n2 of the film 67 and the refractive index n1 of the pillar 62 have the same value, and the refractive index no of the filler 64 is lower than these values (n2=n1 >no).

An example of the material and the refractive index in a case where the wavelength of the light to be detected is 940 nm is as follows.
Pillar 62: amorphous silicon (a-Si), refractive index n1=3.6
Film 67: amorphous silicon (a-Si), refractive index n1=3.6
Filler 64: polymer resin, refractive index n0=1.4

An example of the material and the refractive index in a case where the light to be detected is visible light is as follows.
Pillar 62: titanium oxide TiO₂, refractive index n2=2.56 to 2.87
Film 67: titanium oxide TiO₂, refractive index n2=2.56 to 2.87
Filler 64: none (air region). Refractive index n0=1.0

### Example 3

In Example 3, the film 67 has a refractive index lower than the refractive index of the pillars 62. More specifically, the refractive index n1 of the pillar 62 is the highest, the refractive index no of the filler 64 is the lowest, and the refractive index n2 of the film 67 is a value therebetween (n1 >n2 >n0).

An example of the material and the refractive index in a case where the wavelength of the light to be detected is 940 nm is as follows.
Pillar 62: amorphous silicon (a-Si), refractive index n1=3.6
Film 67: titanium oxide TiO₂, refractive index n2=2.49
Filler 64: polymer resin, refractive index n0=1.4

Another example is as follows:
Pillar 62: amorphous silicon (a-Si), refractive index n1=3.6
Film 67: zinc peroxide (ZnO₂), refractive index n2=2.13
Filler 64: polymer resin, refractive index n0=1.4

Still another example is as follows.
Pillar 62: amorphous silicon (a-Si), refractive index n1=3.6
Film 67: hafnium oxide (HfO₂), refractive index n2=2.02
Filler 64: polymer resin, refractive index n0=1.4

The cross-sectional shape of the pillars 62 and the film 67 may also be designed differently. For example, the cross-sectional shape of the pillar 62-2 may be devised so as to obtain a larger area of the side surface 62c. By providing more films 67 in the pillar 62-2, a larger effective refractive index difference can be obtained between the pillar 62-1 and the pillar 62-2. Some specific examples will be described as Examples 4 to 6.

### Example 4

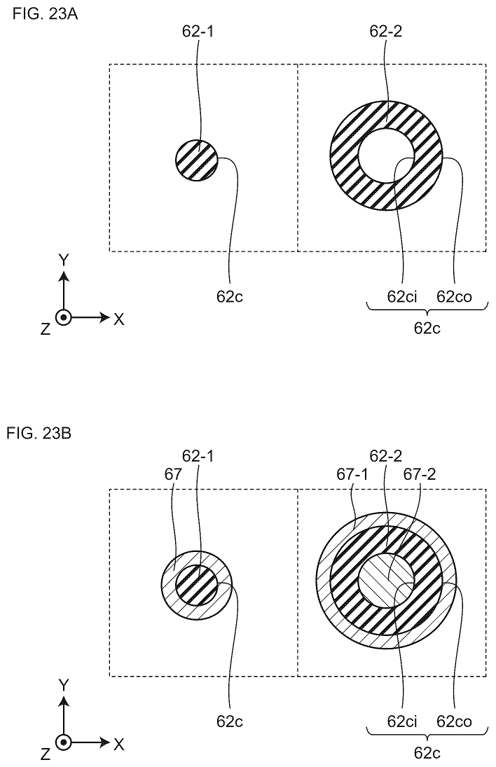

FIG. 23 is a diagram illustrating an example of cross-sectional shapes of the pillar 62 and the film 67. Note that, for reference, (A) of FIG. 23 illustrates the pillar 62 before being covered with the film 67. In part (B) of FIG. 23, the pillar 62 is illustrated covered with the film 67. The same applies to FIGS. 24 and 25 described later.

The pillar 62-1 has a circular cross-sectional shape. The film 67 is provided on the side surface 62c of the pillar 62-1.

The pillar 62-2 has an annular cross-sectional shape. More specifically, the side surface 62c of the pillar 62-2 includes a side surface 62co and a side surface 62ci. The side surface 62co is an outer side surface of the annular ring. The side surface 62ci is an inner side surface of the annular ring. In this example, the film 67 includes a film 67-1 and a film 67-2. The film 67-1 is a first film located outside the annular cross-sectional shape, and is provided on the side surface 62co. The film 67-2 is a second film located inside the annular cross-sectional shape, and is provided on the side surface 62ci and fills the inside of the annular shape.

The annular cross-sectional shape of the pillar 62-2 is larger than the circular cross-sectional shape of the pillar 62-1. As the amount of the film 67-1 provided on the side surface 62c of the pillar 62-2 is larger than the amount of the film 67 provided on the side surface 62c of the pillar 62-1, a larger effective refractive index difference can be obtained.

In one embodiment, the film 67-2 provided on the side surface 62ci of the pillar 62-2 may have a refractive index higher than the refractive index of the film 67-1 provided on the side surface 62co. As a result, a larger effective refractive index difference can be obtained.

### Example 5

FIG. 24 is a diagram illustrating an example of cross-sectional shapes of the pillar 62 and the film 67. The pillar 62-1 has a circular cross-sectional shape. The film 67 is provided on the side surface 62c of the pillar 62-1. The pillar 62-2 has a cross-shaped cross-sectional shape. Since the pillar 62-2 has a cross-shaped cross-sectional shape, the area of the side surface 62c is larger than that in the case of having a circular cross-sectional shape, and more films 67 are provided on the side surface 62c of the pillar 62-2. As a result, a larger effective refractive index difference can be obtained.

### Example 6

FIG. 25 is a diagram illustrating an example of cross-sectional shapes of the pillar 62 and the film 67. The pillar 62-1 has an outer peripheral uneven cross-sectional shape. It can be said that the side surface 62c of the pillar 62 has an uneven shape, is an uneven surface, or the like. The pillar 62-2 also has an outer peripheral uneven cross-sectional shape. The area of the side surface 62c is increased by the presence of the irregularities, and more films 67 are provided. However, this effect becomes apparent as the diameter of the pillar 62 increases. That is, the effect of increasing the film 67 is greater in the pillar 62-2 than in the pillar 62-1. As a result, a larger effective refractive index difference can be obtained.

The reflection suppressing film 63 may be used in combination with the film 67. The effect of suppressing light reflection can be further enhanced. Some specific examples will be described as Example 7 and Example 8.

### Example 7

FIG. 26 is a diagram illustrating an example of a schematic configuration of the optical layer 6. The reflection suppressing film 63 is provided on the upper surface 62a of the pillar 62. A side surface of the reflection suppressing film 63 is referred to as a side surface 63c in the drawing. The film 67 is provided on the side surface 63c so as to also cover (a part of) the side surface 63c out of the upper surface 63a and the side surface 63c of the reflection suppressing film 63. The film 67 has a refractive index higher than the refractive index of the reflection suppressing film 63. The effect of the reflection suppressing film 63 can be maximized.

An example of a manufacturing method will be described. Dry etching is performed using the reflection suppressing film 63 as a mask to form the pillars 62. The film 67 is formed, and the film 67 is etched back to expose the reflection suppressing film 63. Thereafter, the filler 64 is formed.

### Example 8

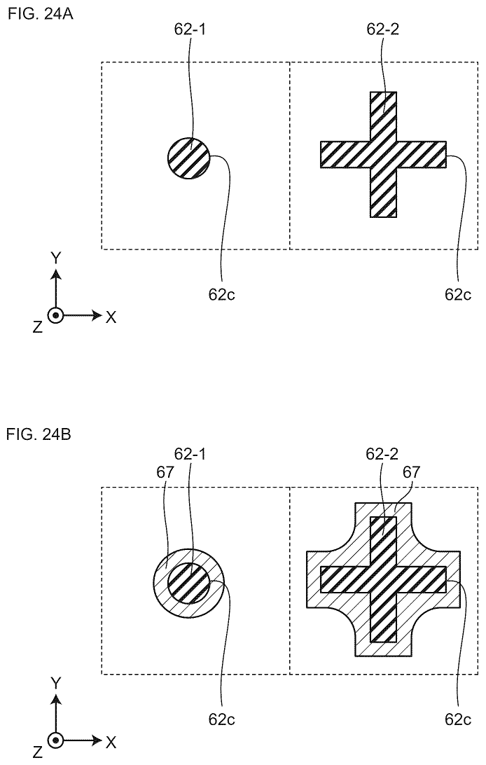

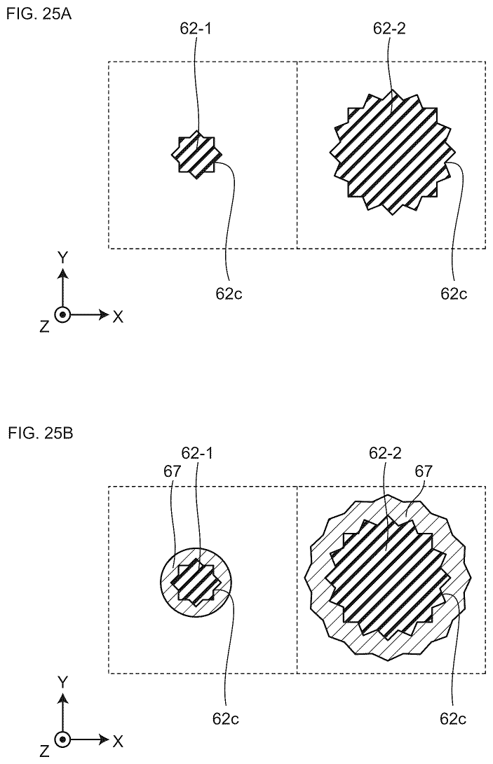

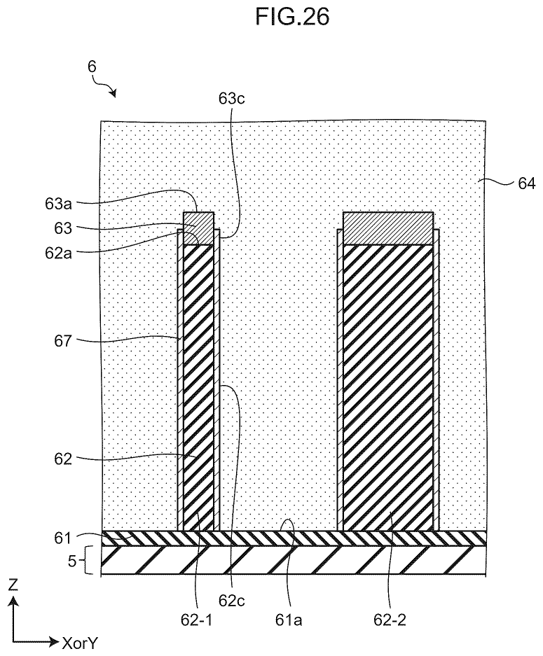

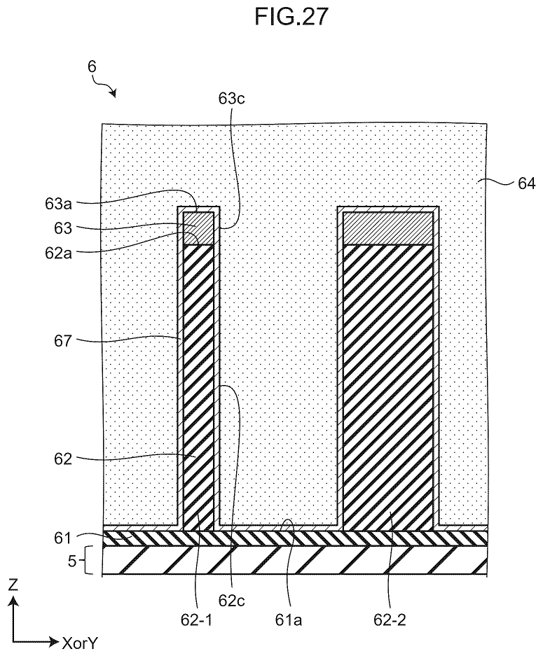

FIG. 27 is a diagram illustrating an example of a schematic configuration of the optical layer 6. The film 67 is also provided on the upper surface 63a and the side surface 63c so as to cover the upper surface 63a and the side surface 63c of the reflection suppressing film 63. The film 67 is also provided on the upper surface 61a of the reflection suppressing film 61. The film 67 has a refractive index lower than the refractive index of the reflection suppressing film 63. By increasing the effective refractive index stepwise toward the pillar 62, the effect of suppressing light reflection can be further enhanced.

An example of a manufacturing method will be described. Dry etching is performed using the reflection suppressing film 63 as a mask to form the pillars 62. Thereafter, the film 67 is formed, and the filler 64 is further formed.

### Example 9

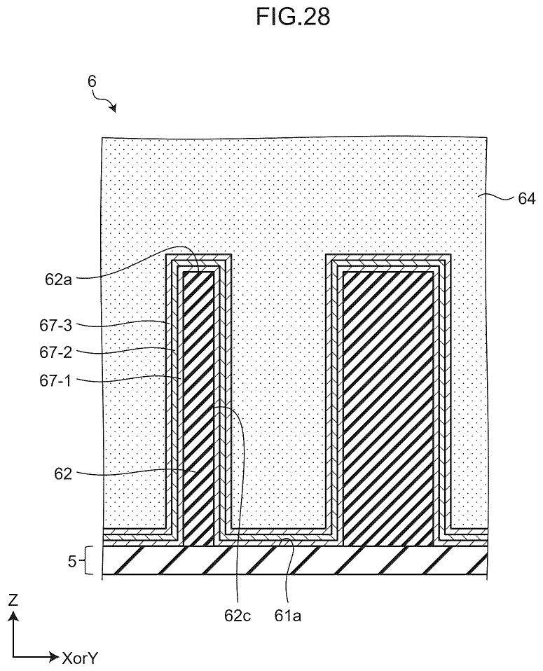

In one embodiment, a plurality of films 67 may be provided. This will be described with reference to FIG. 28.

FIG. 28 is a diagram illustrating an example of a schematic configuration of the optical layer 6. The optical layer 6 includes a plurality of laminated films 67 each having a different refractive index. As the plurality of films 67, three films 67 are illustrated in FIG. 28. Each film 67 is referred to as a film 67-1, a film 67-2, and a film 67-3 in the drawing so as to be distinguishable. In a case where they are not particularly distinguished, they are simply referred to as a film 67.

In this example, the film 67-1, the film 67-2, and the film 67-3 are sequentially laminated in a direction away from the pillar 62. The refractive index of the film 67-1 is closest to the refractive index n1 of the pillar 62. The refractive index of the film 67-3 is closest to the refractive index no of the filler 64. The refractive index of the film 67-2 is a value between the refractive index of the film 67-1 and the refractive index of the film 67-3. Since the plurality of films 67 function as the multilayer reflection suppressing film, reflection suppression can be enhanced.

The plurality of films 67 are obtained by sequentially forming the film 67-1, the film 67-2, and the film 67-3 after forming the pillars 62.

### Example 10

In one embodiment, the material of film 67 may comprise a material having a greater Young's modulus (high Young's modulus material) than the material of pillars 62. By covering the pillars 62 with such a film 67, the effect of suppressing the pillar collapse can be further enhanced.

An example of the material, the refractive index, and the Young's modulus in a case where the wavelength of the light to be detected is 940 nm is as follows.
Pillar 62: amorphous silicon (a-Si), refractive index n1=3.6, Young's modulus=80 Gpa
Film 67: aluminum oxide Al₂O₃, refractive index n2=1.8, Young's modulus=300 Gpa
Filler 64: polymer resin, refractive index n0=1.4

Another example is as follows:
Pillar 62: amorphous silicon (a-Si), refractive index n1=3.6, Young's modulus=80 Gpa
Film 67: titanium oxide TiO₂, refractive index n2=2.49, Young's modulus=130 Gpa
Filler 64: polymer resin, refractive index n0=1.4

### Example 11

In one embodiment of the film 67, the contact angle of the film 67 with respect to the wet-cleaning liquid of the subsequent process may be lower than the angle of the pillars 62 with respect to that cleaning liquid. The pillar collapse can be further suppressed. The hydrophilicity of the surface of the film 67 may be increased by ultraviolet irradiation or the like.

### Example 12

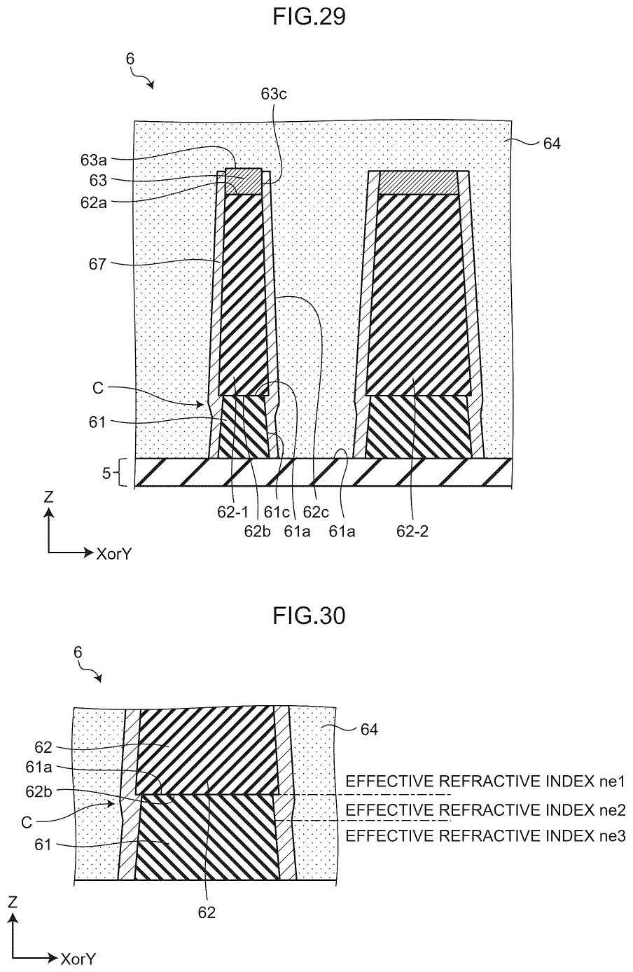

By devising the shape of the boundary portion between the reflection suppressing film 61 and the pillars 62, it is also possible to suppress peeling of the film 67 and enhance the effect of suppressing light reflection. This will be described with reference to FIGS. 29 and 30.

FIG. 29 is a diagram illustrating an example of a schematic configuration of the optical layer 6. In this example, the optical layer 6 includes a plurality of reflection suppressing films 61 each provided on the lower surface 62b of the corresponding pillar 62. A side surface of the reflection suppressing film 61 is referred to as a side surface 61c in the drawing. The film 67 is provided on the side surface 62c so as to also cover the side surface 62c of the reflection suppressing film 61.

The lower surface 62b of the pillar 62 and the upper surface 61a of the reflection suppressing film 61 are in surface contact with each other. The lower surface 62b of the pillar 62 and the upper surface 61a of the reflection suppressing film 61 have areas different from each other. In this example, the upper surface 61a of the reflection suppressing film 61 has an area smaller than the area of the lower surface 62b of the pillar 62. Due to the area gap, a constriction C is formed at the boundary surface between the pillar 62 and the reflection suppressing film 61.

In this example, the film 67 is provided to fill the constriction C. The constriction C is provided with more films 67 than the other portions. That is, the thickness of a portion of the film 67 located in the constriction C is larger than the thicknesses of other portions. By providing many films 67, it is possible to suppress peeling of the film 67 at the interface between the pillar 62 and the reflection suppressing film 61.

In addition, by providing more films 67 in the portion of the constriction C than other portions, the effective refractive index changes stepwise, and light reflection can be suppressed accordingly. A description will be given with reference to FIG. 30.

FIG. 30 is an enlarged view of the constriction C and its periphery. The effective refractive index of the region where the pillar 62 is located in the Z-axis direction is referred to as an effective refractive index ne1. The effective refractive index of the region where the constriction C is located is referred to as an effective refractive index ne2. In the region where the reflection suppressing film 61 is located, the effective refractive index of the region excluding the region where the constriction C is located is referred to as an effective refractive index ne3. Among these effective refractive indexes, the effective refractive index ne1 may be the highest, the effective refractive index ne3 may be the lowest, and the effective refractive index ne2 may be a value therebetween. The effective refractive index can be changed stepwise to further suppress light reflection.

An example of the material, the refractive index, and the Young's modulus in a case where the wavelength of the light to be detected is 940 nm is as follows.
Pillar 62: amorphous silicon (a-Si), refractive index n1=3.6, Young's modulus=80 Gpa
Film 67: titanium oxide TiO₂, refractive index n2=2.49, Young's modulus=130 Gpa
Filler 64: polymer resin, refractive index n0=1.4
Reflection suppressing film 61: silicon nitride (Si₃N₄), refractive index=1.99, Young's modulus=290 Gpa

An example of a manufacturing method will be described. The material of the reflection suppressing film 61, the material of the pillars 62, and the material of the reflection suppressing film 63 are sequentially formed on the substrate (more specifically, for example, on the insulating layer 5). A resist pattern is formed, and the material of the reflection suppressing film 63 is dry-etched using the resist pattern as a mask so as to obtain the reflection suppressing film 63. The material of the pillars 62 is dry-etched using the reflection suppressing film 63 as a mask so as to obtain the pillars 62. Furthermore, the material of the reflection suppressing film 61 is dry-etched so as to obtain the reflection suppressing film 61. At this time, the constriction C is formed at the interface between the pillar 62 and the reflection suppressing film 61. Thereafter, the film 67 is formed. The constriction C is provided with more films 67 than the other portions.

### <Section Summary>

The technology according to the second embodiment described above is specified as follows, for example. One of the disclosed techniques is the photodetector 100. As described with reference to FIGS. 1 to 5, 17 to 30, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the film 67 (which may cover not only the side surface 62c of the pillar 62 but also the upper surface 62a) provided so as to cover at least the side surface 62c of the pillar 62. As a result, the pillars 62 are less likely to fall than in a case where the pillars 62 are not covered with the film 67. Therefore, pillar collapse can be suppressed. Furthermore, the design rule of the pillar 62 can be relaxed. Since the difference in effective refractive index between each pillar 62 and its peripheral region can be increased, desired optical characteristics can be easily obtained. The film 67 can also be used as a reflection suppressing film.

As described with reference to FIG. 28 and the like, the optical layer 6 may include a plurality of films 67 (for example, films 67-1 to 67-3) each having a different refractive index and laminated. For example, the effect of suppressing light reflection can be enhanced by causing the plurality of films 67 to function as a multilayer reflection suppressing film.

As described with reference to FIGS. 17, 21, 22, 26 to 30, and the like, the optical layer 6 may include the filler 64 that fills the space between the plurality of pillars 62 and is provided on the film 67. The effect of suppressing the pillar collapse can be further enhanced.

As described with reference to FIGS. 21 and 22 and the like, the film 67 may have a refractive index lower than the refractive index of the filler 64. The film 67 may have the same refractive index as the refractive index of the filler 64. The film 67 may have a refractive index higher than the refractive index of the filler 64. For example, the film 67 and the filler 64 having various refractive indexes as described above can be used.

As described with reference to FIGS. 19 to 24 and the like, the plurality of pillars 62 may include pillars 62 having a circular cross-sectional shape. For example, by covering the side surface 62c of the pillar 62 having such a cross-sectional shape with the film 67, it is possible to increase the difference in effective refractive index between the pillars 62 having different diameters and their peripheral regions.

As described with reference to FIG. 23 and the like, the plurality of pillars 62 may include the pillars 62 having an annular cross-sectional shape larger than the circular cross-sectional shape. The film 67 in that case may include the film 67-1 (first film) located outside the annular cross-sectional shape and the film 67-2 (second film) located inside the annular cross-sectional shape. The film 67-2 may have a refractive index higher than the refractive index of the pillars 62. As a result, a larger effective refractive index difference can be obtained. Further, as described with reference to FIG. 24 and the like, the plurality of pillars 62 may include pillars having a cross-shaped cross-sectional shape larger than the circular cross-sectional shape. As described with reference to FIG. 25 and the like, the plurality of pillars 62 may include the pillars 62 having the outer peripheral uneven cross-sectional shape.

As described with reference to FIGS. 26, 27, 29, and the like, the optical layer 6 may include the reflection suppressing film 63 that can be provided on the upper surface 62a of the pillar 62. The effect of suppressing light reflection can be further enhanced.

As described with reference to FIG. 26 and the like, the film 67 may be provided so as to cover the side surface 62c of the reflection suppressing film 63 and the side surface 63c of the upper surface 63a. In that case, the film 67 may have a refractive index higher than the refractive index of the reflection suppressing film 63. The effect of the reflection suppressing film 63 can be maximized.

As described with reference to FIG. 27 and the like, the film 67 may also be provided so as to cover the side surface 63c and the upper surface 63a of the reflection suppressing film 63. The film 67 may have a refractive index lower than the refractive index of the pillars 62. The effective refractive index is increased stepwise, and the effect of suppressing light reflection can be further enhanced.

As described with reference to FIGS. 29, 30, and the like, the optical layer 6 may include the reflection suppressing film 61 provided on the lower surface 62b of the pillar 62, the film 67 may be provided so as to also cover the side surface 61c of the reflection suppressing film 61, and the constriction C may be formed at the interface between the pillar 62 and the reflection suppressing film 61. The film 67 may be provided to fill the constriction C. Since many films 67 are provided in the constriction C, peeling of the film 67 at the interface between the pillar 62 and the reflection suppressing film 61 can be suppressed.

The film 67 may have a Young's modulus greater than the Young's modulus of the pillars 62. By covering the pillars 62 with the film 67 having a high Young's modulus, the effect of suppressing the pillar collapse can be further enhanced.

The contact angle of the film 67 with respect to the cleaning liquid may be lower than the angle of the pillar 62 with respect to the cleaning liquid. The pillar collapse can be further suppressed.

### 4. Fourth Embodiment

In the fourth embodiment, the pillar collapse is suppressed by devising the shape of the reflection suppressing film 63.

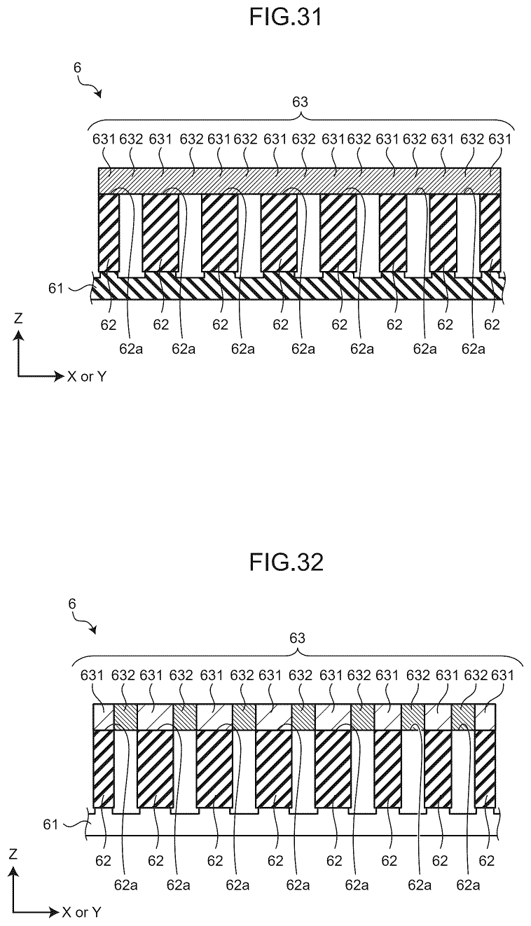

FIGS. 31 and 32 are diagrams illustrating an example of a schematic configuration of the optical layer 6. The reflection suppressing film 63 is provided over the upper surfaces 62a of the plurality of pillars 62. The reflection suppressing film 63 includes a plurality of first portions 631 and a plurality of second portions 632. Each of the plurality of first portions 631 is located on the upper surface 62a of the corresponding pillar 62. Each of the plurality of second portions 632 connects the first portions 631 located on the upper surfaces 62a of the adjacent pillars 62.

By providing the reflection suppressing film 63 over the upper surfaces 62a of the plurality of pillars 62, it is possible to enhance fixation of each pillar 62 and suppress the pillar collapse. For example, a drying process during WET treatment, pattern collapse due to static electricity, and the like can be suppressed. Note that the first portion 631 of the reflection suppressing film 63 can also be referred to as a fall prevention reinforcing beam or the like.

In the example illustrated in FIG. 31, the material of the second portion 632 is the same as the material of the first portion 631. The entire reflection suppressing film 63 including the first portion 631 and the second portion 632 may be integrally formed. In contrast, in the example illustrated in FIG. 32, the material of the second portion 632 is different from the material of the first portion 631. For example, the design range of the intensity, refractive index, and the like of the second portion 632 can be expanded.

FIGS. 33 to 48 are diagrams illustrating an example of a manufacturing method.

FIGS. 33 to 40 illustrate examples of manufacturing methods where the material of the second portion 632 is the same as the material of the first portion 631.

As illustrated in FIG. 33, the pillar material 62m is provided on the reflection suppressing film 61 provided on the insulating layer 5. The photoresist PR having a pattern matching a pillar shape is provided using a lithography technique. The photoresist PR exemplified is a multilayer resist.

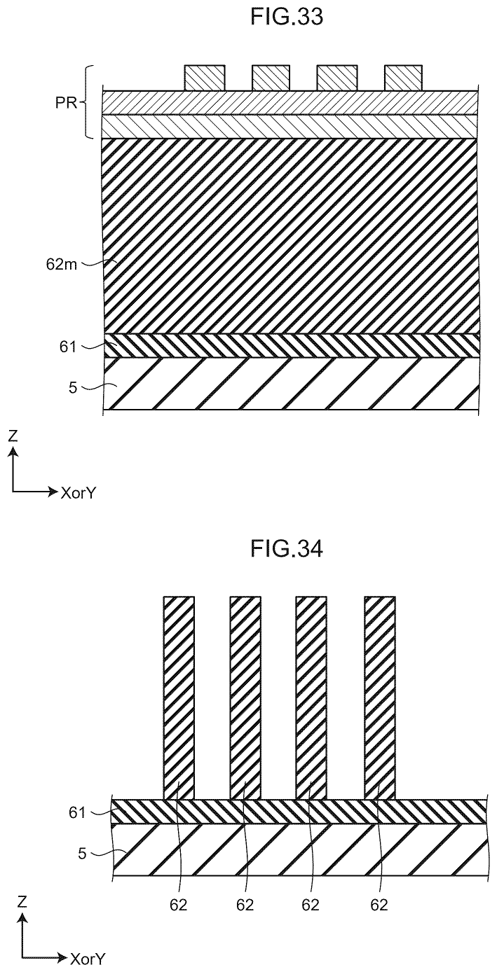

As illustrated in FIG. 34, the pillar material 62m is processed by dry etching or the like to obtain the pillar 62.

As illustrated in FIG. 35, a sacrificial layer S is formed so as to cover the reflection suppressing film 61 and the pillars 62.

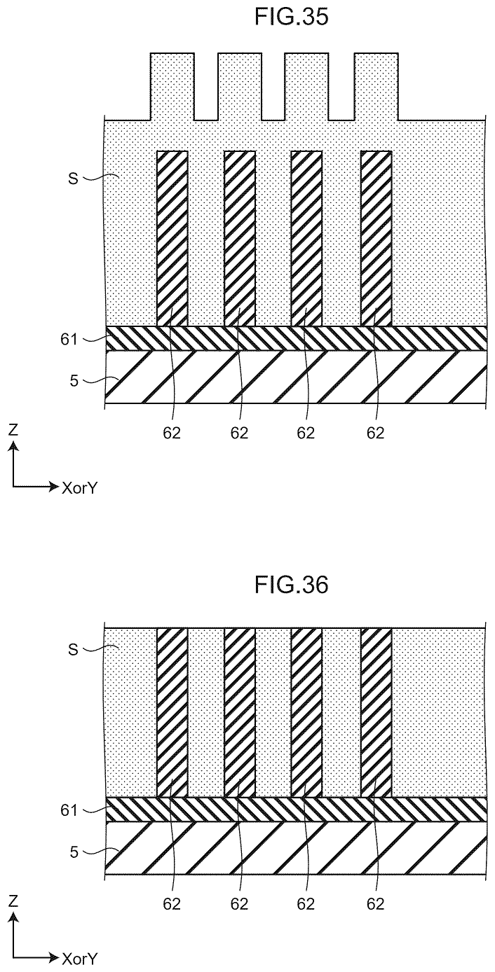

As illustrated in FIG. 36, the sacrificial layer S is planarized so that the sacrificial layer S has the same thickness as the height of the pillar 62.

As illustrated in FIG. 37, the reflection suppressing film 63 is formed so as to cover the sacrificial layer S and the pillars 62. A portion located on the upper surface 62a of the pillar 62 is the first portion 631. A portion located between the first portions 631 on the adjacent pillars 62 is the second portion 632. The reflection suppressing film 63 including the first portion 631 and the second portion 632 is obtained.

As illustrated in FIG. 38, a fine hole 630 is formed in a part of the reflection suppressing film 63, for example, a portion away from the pillars 62.

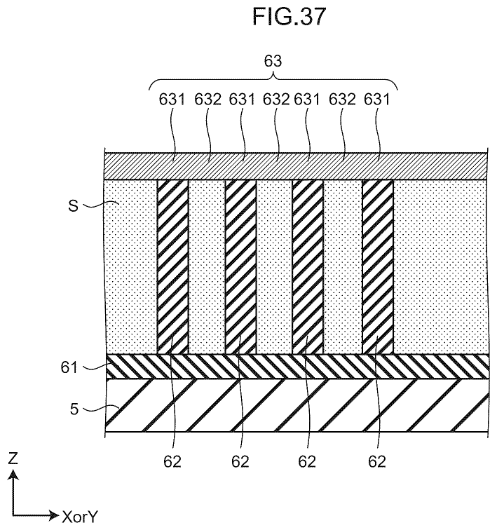

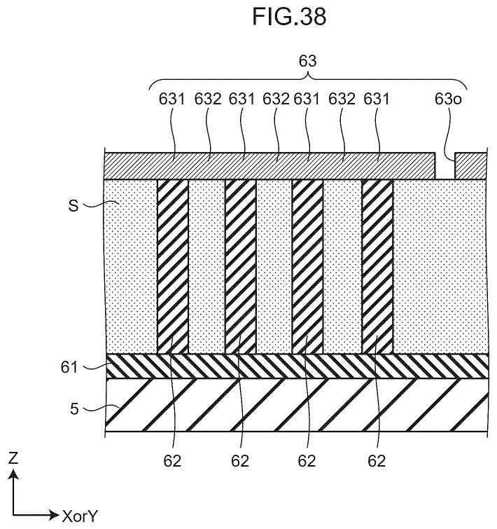

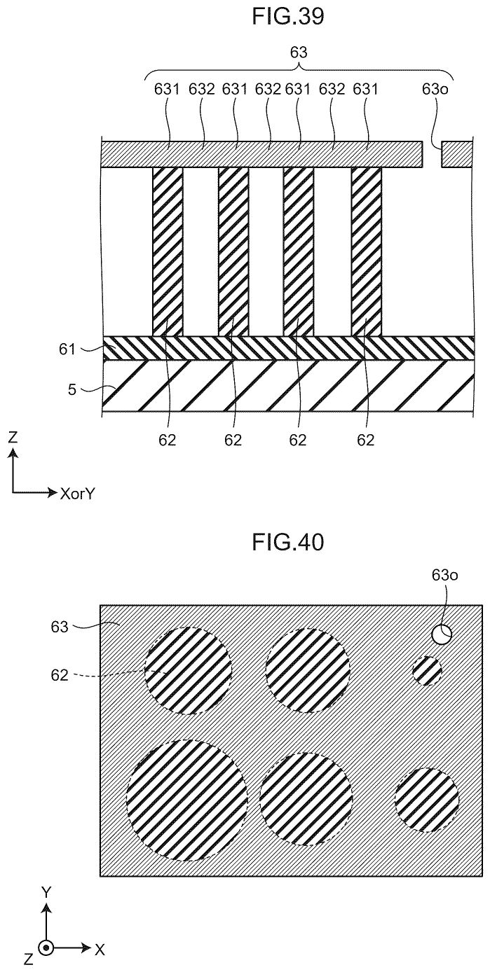

As illustrated in FIG. 39, the sacrificial layer S is removed through the fine hole 630. Note that, as illustrated in FIG. 40, the reflection suppressing film 63 having the fine hole 630 is observed in plan view (when viewed in the Z-axis negative direction). In the drawing, the pillar 62 located below the reflection suppressing film 63 is indicated by a broken line.

The wafer process ends and dicing is performed. Note that, in one embodiment, another optical layer 6 may be further formed thereon. In the case of obtaining such a multistage configuration of the optical layer 6, the process of removing the sacrificial layer S may be moved to the subsequent step as necessary.

FIGS. 41 to 48 illustrate examples of manufacturing methods in a case where the material of the second portion 632 is different from the material of the first portion 631. The material of the first portion 631 is referred to as a first partial material 631m.

As illustrated in FIG. 41, the pillar material 62m and the first partial material 631m are sequentially provided on the reflection suppressing film 61 provided on the insulating layer 5. Further, the photoresist PR having a pattern matching the shape of the pillar 62 is provided.

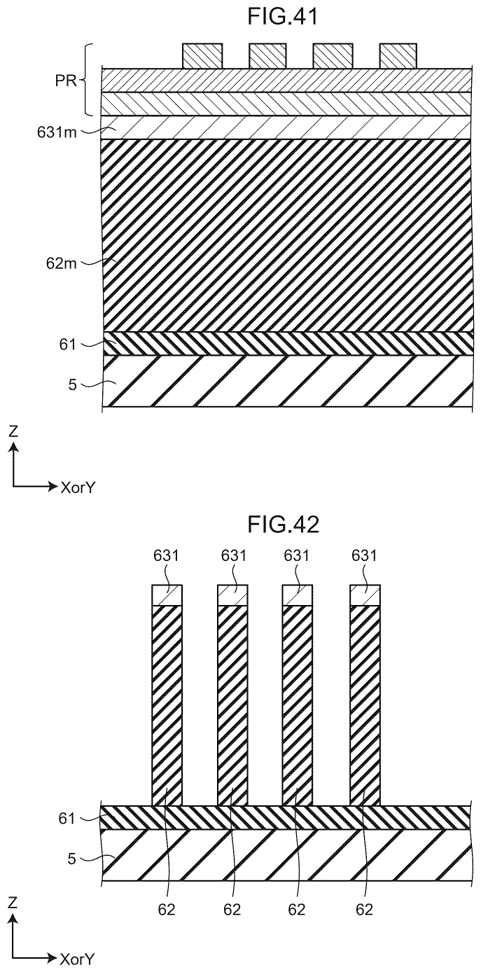

As illustrated in FIG. 42, the first partial material 631m and the pillar material 62m are processed by dry etching or the like. The first portion 631 and the pillars 62 are obtained.

As illustrated in FIG. 43, the sacrificial layer S is formed so as to cover the reflection suppressing film 61, the pillars 62, and the first portion 631.

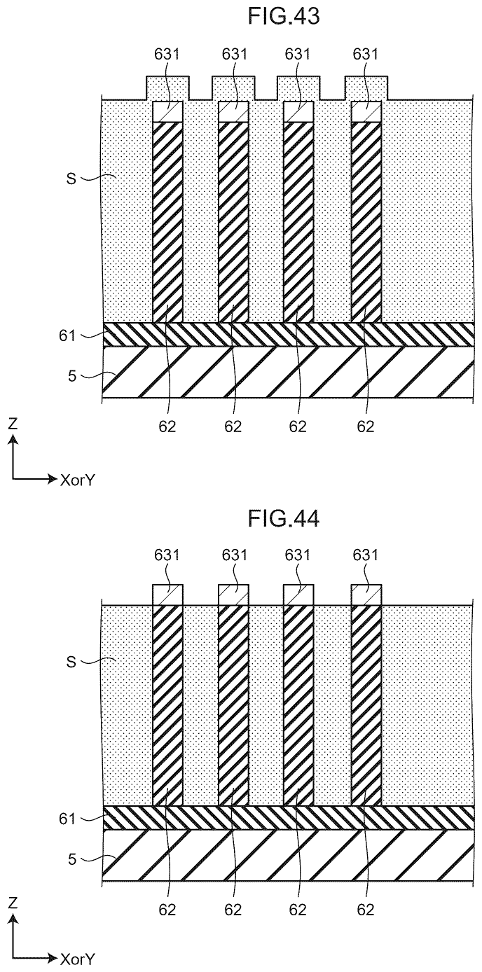

As illustrated in FIG. 44, the sacrificial layer S is etched back so that the upper surface and the side surface of the first portion 631 are exposed.

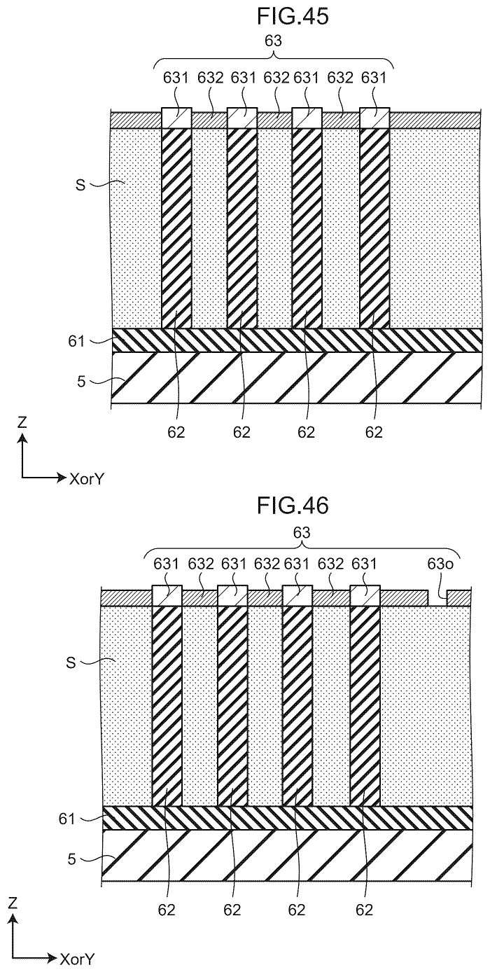

As illustrated in FIG. 45, the second portion 632 is selectively provided (for example, selectively grown) on the sacrificial layer S. The reflection suppressing film 63 including the first portion 631 and the second portion 632 is obtained. Note that, instead of selective growth, film formation on the entire surface and etch-back or planarization may be used in combination.

As illustrated in FIG. 46, the fine hole 630 is formed in a part of the reflection suppressing film 63, for example, a portion away from the pillars 62.

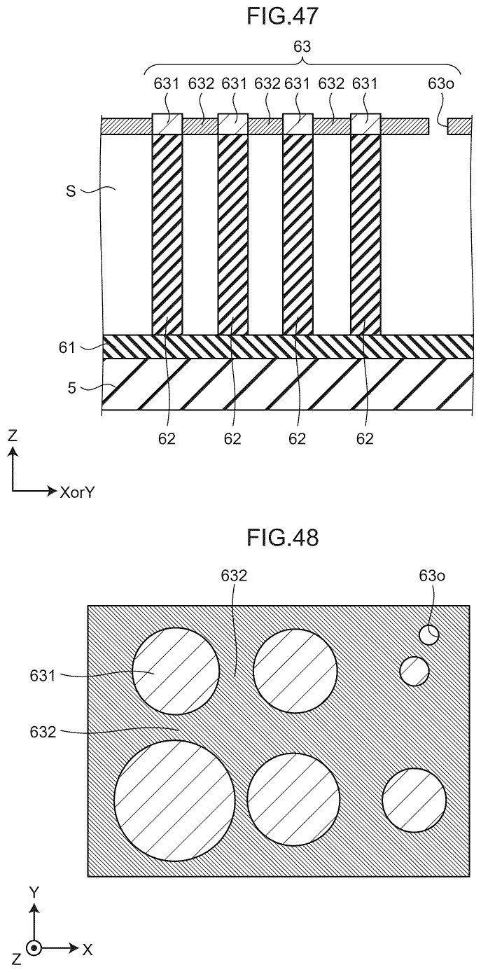

As illustrated in FIG. 47, the sacrificial layer S is removed through the fine hole 630. Note that, as illustrated in FIG. 48, the reflection suppressing film 63 having the fine hole 630 is observed in plan view.

### <Section Summary>

The technology according to the second embodiment described above is specified as follows, for example. One of the disclosed techniques is the photodetector 100. As described with reference to FIGS. 1 to 5, 31, 32, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the reflection suppressing film 63 provided over the upper surfaces 62a of the plurality of pillars 62. The reflection suppressing film 63 includes the first portion 631 located on the upper surface 62a of the corresponding pillar 62 and the second portion 632 connecting the first portions 631 located on the upper surface 62a of the adjacent pillar 62. As a result, the fixation of each pillar 62 can be enhanced, and the pillar collapse can be suppressed.

As described with reference to FIG. 31 and the like, the material of the second portion 632 may be the same as the material of the first portion 631. In this case, for example, the reflection suppressing film 63 including the first portion 631 and the second portion 632 can be integrally formed.

As described with reference to FIG. 32 and the like, the material of the second portion 632 may be different from the material of the first portion 631. In this case, for example, the design range of the second portion 632 can be increased. 5. Conclusion

The embodiments of the present disclosure have been described above. The pillar collapse can be suppressed by various techniques described so far. Note that the effects described in the present disclosure are merely examples and are not limited to the disclosed contents. There may be other effects.

The technical scope of the present disclosure is not limited to the above-described embodiments as it is, and various modifications can be made without departing from the gist of the present disclosure. In addition, components of different embodiments and modifications may be appropriately combined.

Note that the disclosed technology can also have the following configurations.

(1)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a filler provided to fill a space between the plurality of pillars, and
a side surface of the pillar has a curved surface bulging toward an outside of the pillar.
   (2)

The photodetector according to (1), wherein the pillar includes:
an upper end portion having an upper surface of the pillar;
a lower end portion having a lower surface of the pillar; and
an intermediate portion located between the upper end portion and the lower end portion and having a width larger than a width of any of the upper end portion and the lower end portion.
   (3)

The photodetector according to (2), wherein
the intermediate portion has a cross-sectional area larger than an area of either the upper surface or the lower surface.
   (4)

The photodetector according to any one of (1) to (3), wherein
the optical layer includes a film provided to cover the upper surface of the pillar, and
the film is located inside the pillar when the pillar is viewed in plan view.
   (5)

The photodetector according to any one of (1) to (4), wherein
the side surface of the pillar further has a curved surface recessed toward an inside of the pillar.
   (6)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section;
a reflection suppressing film provided on a lower surface of the pillar; and
a filler provided to fill a space between the plurality of pillars and cover the reflection suppressing film, and
the reflection suppressing film includes:
an upper end portion located on the lower surface of the pillar and having an upper surface of the reflection suppressing film;
a lower end portion having a lower surface of the reflection suppressing film; and
an intermediate portion located between the upper end portion and the lower end portion and having a width smaller than a width of the upper end portion.
   (7)

The photodetector according to (6), wherein
a side surface of the reflection suppressing film has a curved surface recessed inward.
   (8)

The photodetector according to (7), wherein
a depression is formed at an interface between the upper surface of the reflection suppressing film and the lower surface of the pillar, and
the depression is filled with the filler.
   (9)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a film provided to cover at least a side surface of the pillar.
   (10)

The photodetector according to (9), wherein
the film is provided to cover an upper surface of the pillar.
   (11)

The photodetector according to (9) or (10), wherein
the optical layer includes a plurality of the film each having a different refractive index and laminated.
   (12)

The photodetector according to any one of (9) to (11), wherein
the optical layer includes a filler provided to fill a space between the plurality of pillars and cover the film.
   (13)

The photodetector according to (12), wherein
the film has a refractive index lower than a refractive index of the filler.
   (14)

The photodetector according to (12), wherein
the film has a refractive index same as a refractive index of the filler.
   (15)

The photodetector according to (12), wherein
the film has a refractive index higher than a refractive index of the filler.
   (16)

The photodetector according to any one of (9) to (15), wherein
the plurality of pillars include pillars having a circular cross-sectional shape.
   (17)

The photodetector according to (16), wherein
the plurality of pillars include pillars having an annular cross-sectional shape larger than the circular cross-sectional shape.
   (18)

The photodetector according to (17), wherein
the film includes:
a first film located outside the annular cross-sectional shape; and
a second film located inside the annular cross-sectional shape.
   (19)

The photodetector according to (18), wherein
the second film has a refractive index higher than a refractive index of the pillar.
   (20)

The photodetector according to any one of (16) to (19), wherein
the plurality of pillars include pillars having a cross-shaped cross-sectional shape larger than the circular cross-sectional shape.
   (21)

The photodetector according to any one of (16) to (20), wherein
the plurality of pillars include pillars having an outer peripheral uneven cross-sectional shape.
   (22)

The photodetector according to any one of (9) to (21), wherein
the optical layer includes a reflection suppressing film provided on the upper surface of the pillar.
   (23)

The photodetector according to (22), wherein
the film is provided to also cover one of a side surface and an upper surface of the reflection suppressing film.
   (24)

The photodetector according to (23), wherein
the film has a refractive index higher than a refractive index of the reflection suppressing film.
   (25)

The photodetector according to (22), wherein
the film is also provided to cover a side surface and an upper surface of the reflection suppressing film.
   (26)

The photodetector according to (25), wherein
the film has a refractive index lower than a refractive index of the pillar.
   (27)

The photodetector according to any one of (9) to (26), wherein
the optical layer includes a reflection suppressing film provided on a lower surface of the pillar,
the film is provided to also cover a side surface of the reflection suppressing film, and
a constriction is formed at an interface between the pillar and the reflection suppressing film.
   (28)

The photodetector according to (27), wherein
the film is provided to fill the constriction.
   (29)

The photodetector according to any one of (9) to (28), wherein
the film has a Young's modulus larger than a Young's modulus of the pillar.
   (30)

The photodetector according to any one of (9) to (29), wherein
a contact angle of the film with respect to the cleaning liquid is lower than an angle of the pillar with respect to the cleaning liquid.
   (31)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a reflection suppressing film provided over upper surfaces of the plurality of pillars, and
the reflection suppressing film includes:
a first portion each located on the upper surface of the pillar corresponding; and
a second portion connecting the first portions located on the upper surfaces of the pillars adjacent.
   (32)

The photodetector according to (31), wherein
a material of the second portion is same as a material of the first portion.
   (33)

The photodetector according to (31), wherein
a material of the second portion is different from a material of the first portion.

### REFERENCE SIGNS LIST

1 PIXEL ARRAY SECTION
2 PIXEL
21 PHOTOELECTRIC CONVERSION SECTION
22 CHARGE HOLDING SECTION
23 TRANSISTOR
24 TRANSISTOR
25 TRANSISTOR
26 TRANSISTOR
3 SEMICONDUCTOR SUBSTRATE
3a UPPER SURFACE
3b LOWER SURFACE
31 SEPARATION REGION
4 FIXED CHARGE FILM
5 INSULATING LAYER
51 INSULATING FILM
52 LIGHT SHIELDING FILM
53 INSULATING FILM
6 OPTICAL LAYER
61 REFLECTION SUPPRESSING FILM
61a UPPER SURFACE
61b LOWER SURFACE
62 PILLAR
62a UPPER SURFACE
62b LOWER SURFACE
62c SIDE SURFACE
621 UPPER END PORTION
622 LOWER END PORTION
623 INTERMEDIATE PORTION
63 REFLECTION SUPPRESSING FILM
63a UPPER SURFACE
63b LOWER SURFACE
631 FIRST PORTION
632 SECOND PORTION
64 FILLER
65 PROTECTIVE FILM
66 LTO FILM
67 FILM
7 WIRING LAYER
8 INSULATING LAYER
9 SUPPORT SUBSTRATE
C CONSTRICTION
dp DEPRESSION
100 PHOTODETECTOR

1. A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a filler provided to fill a space between the plurality of pillars, and
a side surface of the pillar has a curved surface bulging toward an outside of the pillar.

2. The photodetector according to claim 1, wherein
the pillar includes:
an upper end portion having an upper surface of the pillar;
a lower end portion having a lower surface of the pillar; and
an intermediate portion located between the upper end portion and the lower end portion and having a width larger than a width of any of the upper end portion and the lower end portion.

3. The photodetector according to claim 2, wherein
the intermediate portion has a cross-sectional area larger than an area of either the upper surface or the lower surface.

4. The photodetector according to claim 1, wherein
the optical layer includes a film provided to cover the upper surface of the pillar, and
the film is located inside the pillar when the pillar is viewed in plan view.

5. The photodetector according to claim 1, wherein
the side surface of the pillar further has a curved surface recessed toward an inside of the pillar.

6. A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section;
a reflection suppressing film provided on a lower surface of the pillar; and
a filler provided to fill a space between the plurality of pillars and cover the reflection suppressing film, and
the reflection suppressing film includes:
an upper end portion located on the lower surface of the pillar and having an upper surface of the reflection suppressing film;
a lower end portion having a lower surface of the reflection suppressing film; and
an intermediate portion located between the upper end portion and the lower end portion and having a width smaller than a width of the upper end portion.

7. The photodetector according to claim 6, wherein
a side surface of the reflection suppressing film has a curved surface recessed inward.

8. The photodetector according to claim 7, wherein
a depression is formed at an interface between the upper surface of the reflection suppressing film and the lower surface of the pillar, and
the depression is filled with the filler.

9. A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a film provided to cover at least a side surface of the pillar.

10. The photodetector according to claim 9, wherein
the film is provided to cover an upper surface of the pillar.

11. The photodetector according to claim 9, wherein
the optical layer includes a plurality of the film each having a different refractive index and laminated.

12. The photodetector according to claim 9, wherein
the optical layer includes a filler provided to fill a space between the plurality of pillars and cover the film.

13. The photodetector according to claim 12, wherein
the film has a refractive index lower than a refractive index of the filler.

14. The photodetector according to claim 12, wherein
the film has a refractive index same as a refractive index of the filler.

15. The photodetector according to claim 12, wherein
the film has a refractive index higher than a refractive index of the filler.

16. The photodetector according to claim 9, wherein
the plurality of pillars include pillars having a circular cross-sectional shape.

17. The photodetector according to claim 16, wherein
the plurality of pillars include pillars having an annular cross-sectional shape larger than the circular cross-sectional shape.

18. The photodetector according to claim 17, wherein
the film includes:
a first film located outside the annular cross-sectional shape; and
a second film located inside the annular cross-sectional shape.

19. The photodetector according to claim 18, wherein
the second film has a refractive index higher than a refractive index of the pillar.

20. The photodetector according to claim 16, wherein
the plurality of pillars include pillars having a cross-shaped cross-sectional shape larger than the circular cross-sectional shape.

21. The photodetector according to claim 16, wherein
the plurality of pillars include pillars having an outer peripheral uneven cross-sectional shape.

22. The photodetector according to claim 9, wherein
the optical layer includes a reflection suppressing film provided on the upper surface of the pillar.

23. The photodetector according to claim 22, wherein
the film is provided to also cover one of a side surface and an upper surface of the reflection suppressing film.

24. The photodetector according to claim 23, wherein
the film has a refractive index higher than a refractive index of the reflection suppressing film.

25. The photodetector according to claim 22, wherein
the film is also provided to cover a side surface and an upper surface of the reflection suppressing film.

26. The photodetector according to claim 25, wherein
the film has a refractive index lower than a refractive index of the pillar.

27. The photodetector according to claim 9, wherein
the optical layer includes a reflection suppressing film provided on a lower surface of the pillar,
the film is provided to also cover a side surface of the reflection suppressing film, and
a constriction is formed at an interface between the pillar and the reflection suppressing film.

28. The photodetector according to claim 27, wherein
the film is provided to fill the constriction.

29. The photodetector according to claim 9, wherein
the film has a Young's modulus larger than a Young's modulus of the pillar.

30. The photodetector according to claim 9, wherein
a contact angle of the film with respect to the cleaning liquid is lower than an angle of the pillar with respect to the cleaning liquid.

31. A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a reflection suppressing film provided over upper surfaces of the plurality of pillars, and
the reflection suppressing film includes:
a first portion each located on the upper surface of the pillar corresponding; and
a second portion connecting the first portions located on the upper surfaces of the pillars adjacent.

32. The photodetector according to claim 31, wherein
a material of the second portion is same as a material of the first portion.

33. The photodetector according to claim 31, wherein
a material of the second portion is different from a material of the first portion.
